(19) United States
(12) Patent Application Publication
(10) Pub. No.: US 2014/0231787 A1
(43) Pub. Date: Aug. 21, 2014

(54) WHITE ORGANIC EL ELEMENT AND ILLUMINATING APPARATUS AND DISPLAY APPARATUS USING THE SAME

(71) Applicant: CANON KABUSHIKI KAISHA, Tokyo (JP)

(72) Inventors: Koichi Ishige, Yokohama-shi (JP); Hiroshi Tanabe, Yokohama-shi (JP); Jun Kamatani, Tokyo (JP); Naoki Yamada, Inagi-shi (JP); Akihito Saitoh, Gotemba-shi (JP)

(73) Assignee: CANON KABUSHIKI KAISHA, Tokyo (JP)

(21) Appl. No.: 14/346,298

(22) PCT Filed: Sep. 20, 2012
(86) PCT No.: PCT/JP2012/005960

§ 371 Date: Mar. 20, 2014

(30) Foreign Application Priority Data
Sep. 22, 2011 (JP) 2011-207325
Jul. 19, 2012 (JP) 2012-160120

(51) Int. Cl. H01L 51/50

(52) U.S. Cl. CPC H01L 51/5004; H01L 51/504
USPC 257/40

(57) ABSTRACT

The present invention provides a white organic EL element improved in durability characteristic.

A light-emitting layer has a laminated configuration including a first light-emitting layer and a second light-emitting layer. A difference in LUMO energy between a host and a blue light-emitting dopant of the first light-emitting layer is set to be larger than a difference in HOMO energy.

### TECHNICAL FIELD

The present invention relates to an organic EL (electroluminescent) element which emits light by supplying a current to an organic EL layer containing a light-emitting layer and sandwiched between a pair of electrodes, particularly to a white organic EL element which emits white light. The present invention also relates to an illuminating apparatus and a display apparatus which use the white organic EL element.

### BACKGROUND ART

In recent years, self-emission type elements for flat panels have attracted attention. The self-emission type elements include a plasma emission display element, a field emission element, an electroluminescent (EL) element, and the like.

Among these, in particular, organic EL elements are energetically studied and developed. An area color-type array to which a color such as green in monochrome is added or blue, red, or any of other colors is further added is already commercialized, and currently full-color is actively developed.

A full-color light-emitting array is formed by a method of coloring a light-emitting layer in a color for each pixel (element) or a method of coloring a color filter in a color for each pixel using a white organic EL element including a white-light emitting layer. The white organic EL element frequently uses two or more types of light-emitting materials. PTL 1 discloses a white organic EL element including a plurality of laminated light-emitting layers, wherein a dopant of a blue light-emitting layer closest to the cathode side has a HOMO (Highest Occupied Molecular Orbital) energy of less than −5.2 eV in order to improve the durability characteristic, operating voltage, and power efficiency.

### CITATION LIST

### Patent Literature

### [PTL 1]

Japanese Translation Patent Publication No. 2011-529614

### Non Patent Literature

### [NPL 1]

Science, 283, 1900 (1999)

### SUMMARY OF INVENTION

### Technical Problem

However, with respect to durability of the organic EL element of PTL 1, a half-time with an initial luminance of 4000 cd/m² is 1100 hours, and further improvement is desired. The present invention provides a white organic EL element improved in durability characteristic.

### Solution to Problem

The present invention relates to a white organic EL element including an anode, a cathode, and a plurality of laminated light-emitting layers sandwiched between the anode and cathode, wherein the plurality of light-emitting layers contain respective dopants having different emission colors; among the plurality of light-emitting layers, the light-emitting layer closest to the cathode side contains a first host and a blue light-emitting dopant, and the other light-emitting layers contain a green light-emitting dopant and a red light-emitting dopant; and Lh1−Lg1>Hg1−Hh1 is satisfied, wherein Lh1 is the lowest unoccupied molecular orbital energy of the first host, Hh1 is the highest occupied molecular orbital energy of the first host, Lg1 is the lowest unoccupied molecular orbital energy of the blue light-emitting dopant, and Hg1 is the highest occupied molecular orbital energy of the blue light-emitting dopant.

In the white organic EL element, the plurality of light-emitting layers include two light-emitting layers; the other light-emitting layer contains a second host, a green light-emitting dopant, and a red light-emitting dopant; and Lh2−Lg2>Hg2−Hh2 is satisfied, wherein Lh2 is the lowest unoccupied molecular orbital energy of the second host, Hh2 is the highest occupied molecular orbital energy of the second host, Lg2 is the lowest unoccupied molecular orbital energy of the green light-emitting dopant, and Hg2 is the highest occupied molecular orbital energy of the green light-emitting dopant.

In the white organic EL element, the first host and the second host are composed of the same material.

In the white organic EL element, the plurality of light-emitting layers include three light-emitting layers; among the other light-emitting layers, the light-emitting layer on the anode side contains a third host and a red light-emitting dopant, and the light-emitting layer on the cathode side contains a second host and a green light-emitting dopant; and Lh2−Lg2>Hh2−Hg2 is satisfied, wherein Lh2 is the lowest unoccupied molecular orbital energy of the second host, Hh2 is the highest occupied molecular orbital energy of the second host, Lg2 is the lowest unoccupied molecular orbital energy of the green light-emitting dopant, and Hg2 is the highest occupied molecular orbital energy of the green light-emitting dopant.

The present invention also relates to an illuminating apparatus including the white organic EL element of the present invention and a converter circuit connected to the white organic EL element.

The present invention further relates to a display apparatus including the white organic EL element of the present invention, and a switching element connected to the white organic EL element.

### Advantageous Effects of Invention

According to the present invention, a white organic EL element improved in durability characteristic can be provided.

### BRIEF DESCRIPTION OF DRAWINGS

FIG. 1 is a schematic sectional view showing an embodiment of the present invention.

FIG. 2 is a schematic sectional view of an example of a display apparatus using an organic EL element of the present invention.

### DESCRIPTION OF EMBODIMENTS

A white organic EL element of the present invention includes a plurality of laminated light-emitting layers. A first light-emitting layer on the cathode side contains a first host and a blue light-emitting dopant, and the other layers contain a green light-emitting dopant and a red light-emitting dopant. In the first light-emitting layer, a difference in lowest unoccupied molecular orbital (LUMO) energy between the host and the dopant is larger than a difference in highest occupied molecular orbital (HOMO) energy.

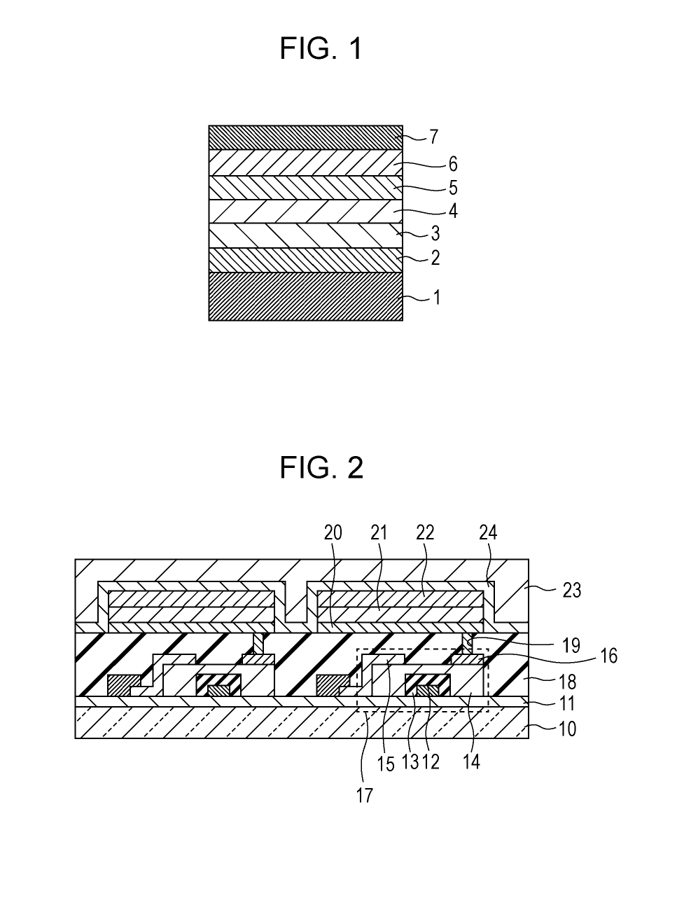

The present invention is described in further detail below with reference to FIG. 1.

FIG. 1 is a schematic sectional view showing an embodiment of the present invention when two light-emitting layers are provided. In this embodiment, an anode 2 and a cathode 7 are provided on a substrate 1, and a first light-emitting layer 5 and a second light-emitting layer 4 are sandwiched between the anode 2 and the cathode 7. The first light-emitting layer 5 and the second light-emitting layer 4 have respective dopants with different emission colors. In addition, a hole transport layer 3 is provided between the anode 2 and the second light-emitting layer 4, and an electron transport layer 6 is provided between the cathode 7 and the first light-emitting layer 5. However, the present invention is not limited to this configuration, and the hole transport layer 3 and the electron transport layer 6 are properly used according to demand. An organic compound layer sandwiched between the anode 2 and the cathode 7 is referred to as an “organic EL layer”.

In addition, the configuration shown in FIG. 1 may further include a hole injection layer provided between the anode 2 and the hole transport layer 3, and an electron blocking layer provided between the hole transport layer 3 and the second light-emitting layer 4. Further, a hole blocking layer may be provided between the first light-emitting layer 5 and the electron transport layer 6, and an electron injection layer may be provided between the electron transport layer 6 and the cathode 7. In the present invention, the hole injection layer, electron blocking layer, hole blocking layer, and electron injection layer are properly used according to demand.

Of the first and second light-emitting layers 5 and 4, the first light-emitting layer 5 disposed on the cathode 7 side contains at least a first host and a blue light-emitting dopant (Bdopant). On the other hand, the second light-emitting layer 4 disposed on the anode 2 side contains at least a second host, a green light-emitting dopant (G dopant), and a red light-emitting dopant (R dopant).

In the present invention, the first light-emitting layer 5 on the cathode 7 side has a relationship satisfying expression (1) below between HOMO and LUMO energies of the first host and the blue light-emitting dopant.

Lh1−Lg1>Hg1−Hh1 (Math. 1)

In the expression, Lh1 is LUMO energy of the first host, Lg1 is LUMO energy of the B dopant, Hh1 is HOMO energy of the first host, and Hg1 is HOMO energy of the B dopant. In the case of ordinary molecules, the HOMO energy and the LUMO energy have negative values on the basis of the vacuum level. In the present invention, a value measured using atmospheric photoelectron spectroscopy (AC-2 manufactured by Riken Keiki Co., Ltd.) is used as the HOMO energy. The LUMO energy is determined from the HOMO energy and a band gap determined from an absorption edge in a visible-ultraviolet absorption spectrum. That is, the LUMO energy is a sum of the HOMO energy and the band gap.

Further, in the specification, when the HOMO energy and the LUMO energy are compared with each other, a smaller value (i.e., in the case of a negative value, a larger absolute value) is referred to as being “deep”, and a larger value (i.e., in the case of a negative value, a smaller absolute value) is referred to as being “shallow”.

This energy relation can improve the durability characteristic. The possible reason for this is as described below.

Non Patent Literature 1 suggests that a cause of deterioration in tris(8-quinolinolate) aluminum (AlQ3) used as a host of a light-emitting layer is instability of radical cation produced by hole electric conduction. In order to suppress the deterioration due to the radical cation in the light-emitting layer, the probability of production of radical cation is decreased by decreasing the hole density in the light-emitting layer. For this purpose, the hole trapping property is decreased and the electron trapping property is increased, thereby increasing the electron density in the light-emitting layer. By increasing the electron density, re-combination probability can be increased, resulting in a decrease in hole density. Therefore, the dopant in the light-emitting layer has an electron trap depth larger than a hole trap depth. In the specification, a light-emitting layer having an electron trap depth larger than a hole trap depth is referred to as an “electron-trapping light-emitting layer”.

In the specification, the term “electron trap depth” represents a value obtained by subtracting the LUMO energy of a dopant from the LUMO energy of a host, and the higher the value, the deeper the electron trap or the larger the trap depth. In addition, the term “hole trap depth” represents a value obtained by subtracting the HOMO energy of a host from the HOMO energy of a dopant, and the higher the value, the deeper the hole trap or the larger the hole trap depth.

Although the electron-trapping light-emitting layer has the effect of improving the durability characteristic, the investigation performed by the inventors showed that the electron-trapping light-emitting layer cannot be easily introduced into a white organic EL element including a plurality of light-emitting layers. Table 1 shows emission intensity ratios of a white organic EL element in which an electron-trapping blue light-emitting layer containing a B dopant and a light-emitting layer containing a R dopant and a G dopant are laminated. The table shows the case of a lamination order where the electron-trapping blue light-emitting layer is disposed on the anode side, and the light-emitting layer containing the R dopant and the G dopant is disposed on the cathode side, and the case of the reverse lamination order.

TABLE 1

| | Intensity ratio | | |
|---|---|---|---|
| | at peak wavelength | | |
| Anode side/cathode side | B | G | R |
| B/(R, G) | 1 | 28 | 35 |
| (R, G)/B | 22 | 26 | 15 |

Table 1 indicates that when the electron-trapping blue light-emitting layer is disposed on the anode side (upper row in Table 1), the emission intensity of blue light is extremely low, thereby making it difficult to use as a white organic EL element. The estimated cause for this is as described below.

When a difference in LUMO energy between the host and dopant is larger than a difference in HOMO energy between the host and dopant, an electron-trapping light-emitting layer shows low electron mobility due to a deep electron trap. In addition, since the hole trap is not deep, hole mobility is not low as long as a host with high mobility is used. Therefore, an emission region is considered to be near the cathode side in the light-emitting layer. In this case, when the light-emitting layer further contains the R and G dopants with a narrow band gap and long wavelengths on the cathode side, energy transfer to the long-wavelength dopants occurs due to the short distance between the exciton of the B dopant and the R and G dopants, thereby weakening emission of blue light. The white organic EL element having off-balanced emission intensities cannot display desired white color. In the use for illumination, a color rendering region is narrowed, and a full-color display panel combined with color filters of RGB three colors requires a large amount of power consumption because a large quantity of current is required for displaying a color with low emission intensity.

On the other hand, as shown in a lower row in Table 1, when the light-emitting layer containing the R and G dopants is disposed on the anode side, and the electron-trapping light-emitting layer containing the B dopant is disposed on the cathode side, the RGB emission balance between intensity ratios at RGB peak wavelengths is improved, thereby making it easy to use as a white organic EL element.

As described above, in the use as a white organic EL element, unlike in a monochromatic light-emitting layer, a good white color cannot be realized unless consideration is given to a relation to another light-emitting layer. In addition, by using the electron-trapping blue light-emitting layer, the blue light-emitting layer having the widest band gap and thus having the lowest durability characteristic among the RGB is improved in durability characteristic, and thus a white organic EL element having high durability characteristic can be achieved.

Further, in the second light-emitting layer 4 disposed on the anode 2 side, the second host and the G dopant can satisfy a relationship of electron trapping property, i.e., a relationship of expression (2) below.

Lh2−Lg2>Hg2−Hh2

In the expression, Lh2 is LUMO energy of the second host, Lg2 is LUMO energy of the G dopant, Hh2 is HOMO energy of the second host, and Hg2 is HOMO energy of the G dopant. The durability characteristic of the white organic EL element can be improved by satisfying the relation of the expression (2).

When, in addition to the first light-emitting layer 5, the second light-emitting layer 4 is made to have the electron trapping property, the driving voltage can be lowered as compared with when the second light-emitting layer 4 has the hole trapping property. This is because the rate of electron mobility is controlled to be low by the first light-emitting layer 5 due to the electron trapping property of the first light-emitting layer 5 on the cathode 7 side. In addition, when the second light-emitting layer 4 has the hole trapping property, the rate of hole mobility is controlled to be low by the second light-emitting layer 4, thereby increasing the driving voltage. In contrast, when the second light-emitting layer 4 has the electron trapping property, the voltage applied to the second light-emitting layer 4 can be decreased due to the high hole mobility, thereby decreasing the driving voltage.

In this embodiment, the R dopant is added to the second light-emitting layer 4, and consequently three-color dopants having different emission wavelengths are added as a whole, thereby realizing a white organic EL element having a wide color reproduction range.

However, since the R dopant and the G dopant having different band gaps are mixed in the second light-emitting layer 4, energy transfer to the R dopant having a narrower band gap easily occurs. Therefore, the dope concentration of the R dopant can be made lower than that of the G dopant. The R dopant concentration by mass ratio is preferably ⅕ or less, more preferably 1/10 or less, of the G dopant concentration. As a result, the emission intensities of the R and G dopants can be balanced.

On the other hand, both the electron trap and the hole trap can be used for the R dopant. Since the R dopant has a low doping concentration and thus has a small influence on mobility and a small influence on the driving voltage.

According to a second embodiment of the present invention, the second light-emitting layer 4 may contain the G dopant, and a third light-emitting layer (not shown) containing the R dopant may be provided on the anode 2 side of the second light-emitting layer 4. The third light-emitting layer contains a third host and the R dopant having a longer wavelength than the G dopant. When three light-emitting layers are provided, energy transfer can be suppressed because dopants having different emission colors are not mixed in the same layer. In particular, this effect is increased by providing the electron-trapping blue and green light-emitting layers, and laminating the first blue light-emitting layer 5, the second green light-emitting layer 4, and the third red light-emitting layer (not shown) in that order from the cathode 7 side. Since the first light-emitting layer 5 and the second green light-emitting layer 4 have the electron trapping property, the emission region of each of the light-emitting layers is considered to be near the cathode 7 side. On the other hand, according to the relation of the lamination order, the light-emitting layer with a narrow band gap which is adjacent to the first light-emitting layer 5 and the second green light-emitting layer 4 is disposed on the anode 2 side. Therefore, excitons can be separated from a material with a narrow band gap, thereby easily suppressing excessive energy transfer to the light-emitting layer having a narrow band gap. As a result, the concentration of the third dopant can be increased as compared with the case of two light-emitting layers, and the manufacturing process can be easily controlled.

On the other hand, in the configuration including the two light-emitting layers as shown in FIG. 1, when the B dopant is added to the first light-emitting layer 5, and the G and R dopants are added to the second light-emitting layer 4, the thickness of the light-emitting layers can be decreased due to a smaller total number of light-emitting layers. The light-emitting layer generally has lower mobility than other layers, and thus the driving voltage can be decreased by thinning the light-emitting layer.

In the specification, the B dopant refers to a light-emitting material having a peak wavelength of 430 nm to 480 nm in an emission spectrum. The G dopant refers to a light-emitting material having a peak wavelength of 500 nm to 570 nm in an emission spectrum. The R dopant refers to a light-emitting material having a peak wavelength of 580 nm to 680 nm in an emission spectrum. The materials of the light-emitting layers used in the present invention are not particularly limited.

Examples of the host materials of the first to third light-emitting layers, the material of the electron injection layer, the material of the electron transport layer, the material of the hole transport layer, and the material of the hole injection layer include compounds having structures represented by Chem. 1 to Chem. 4 below.

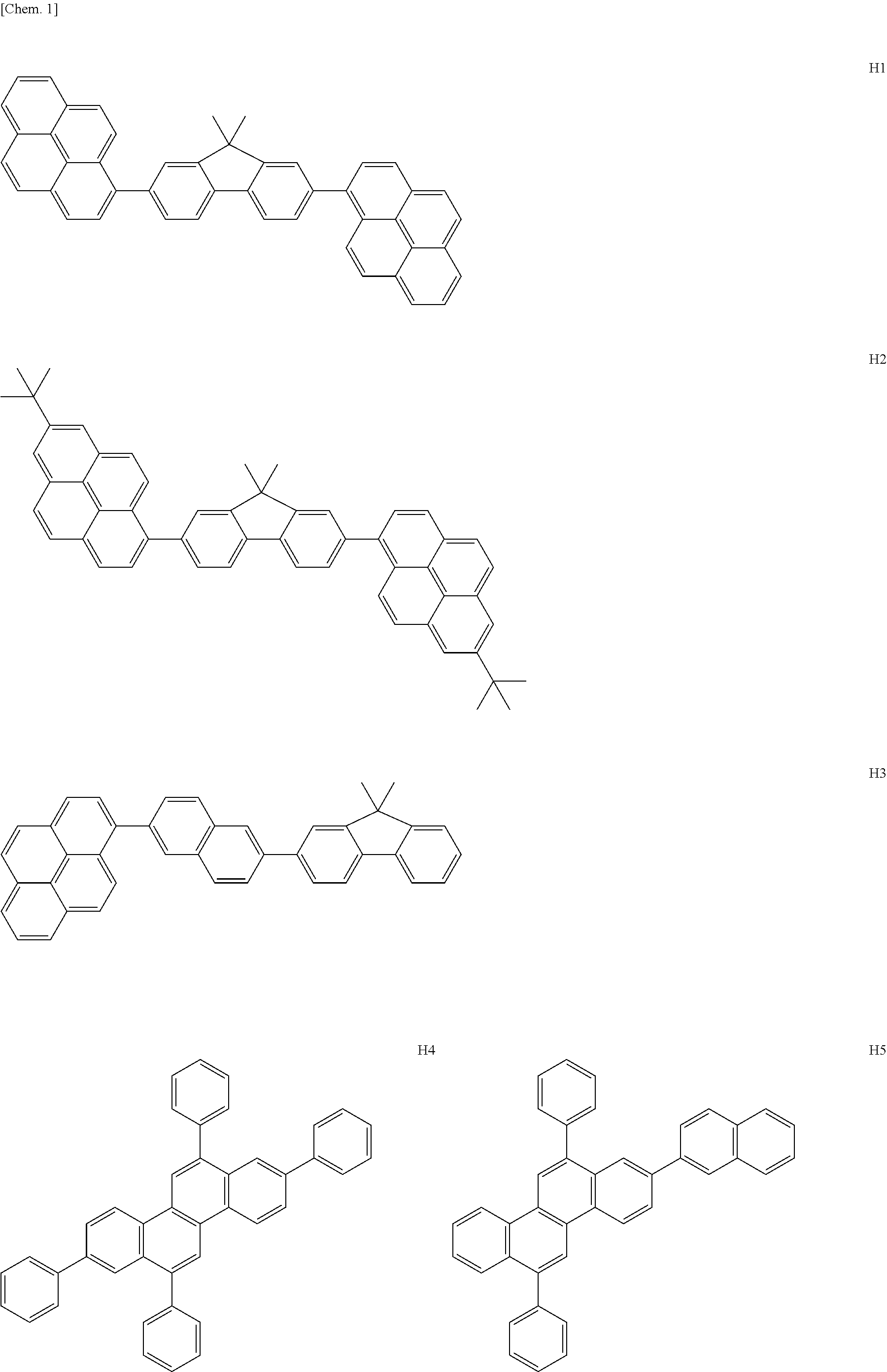

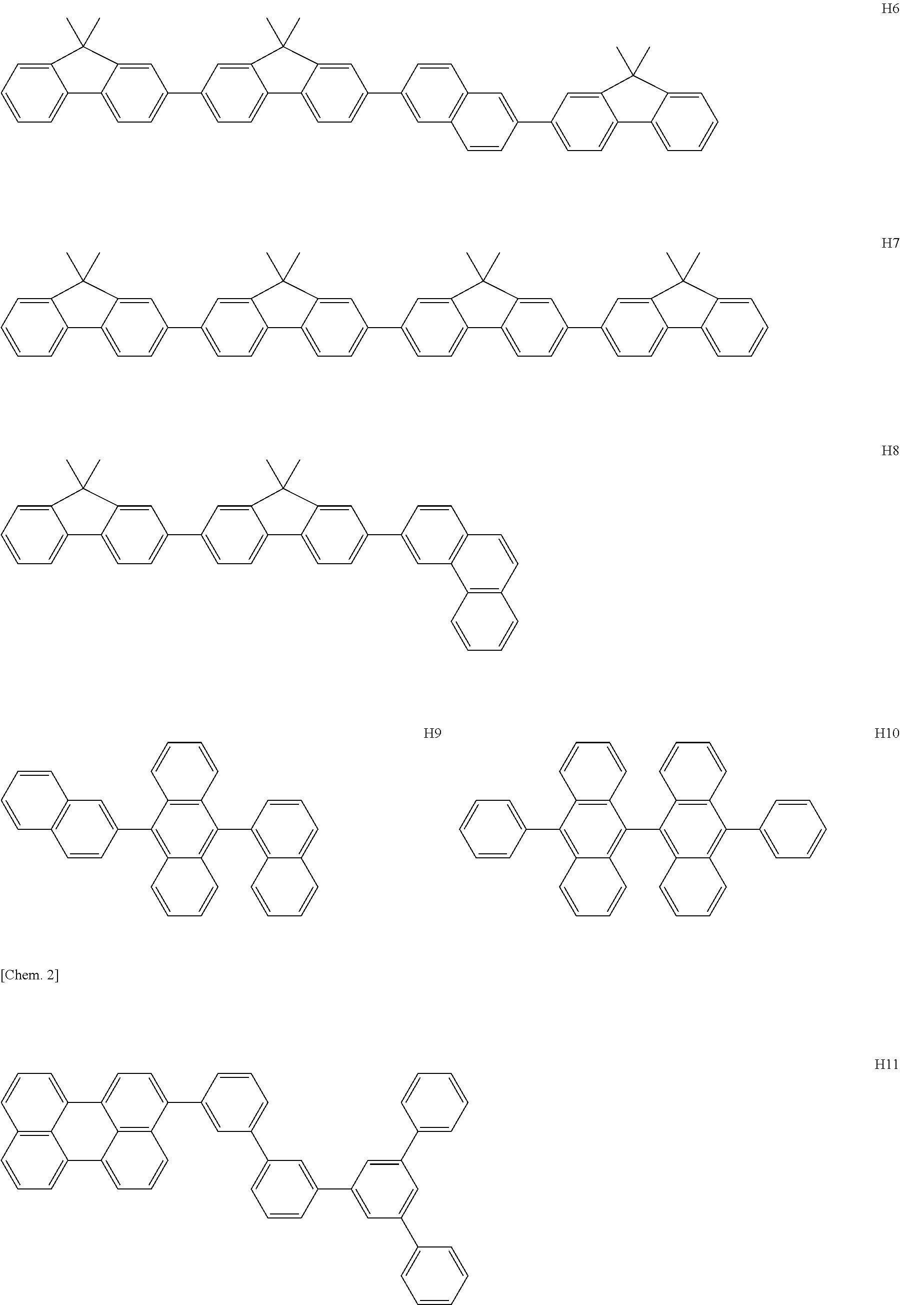

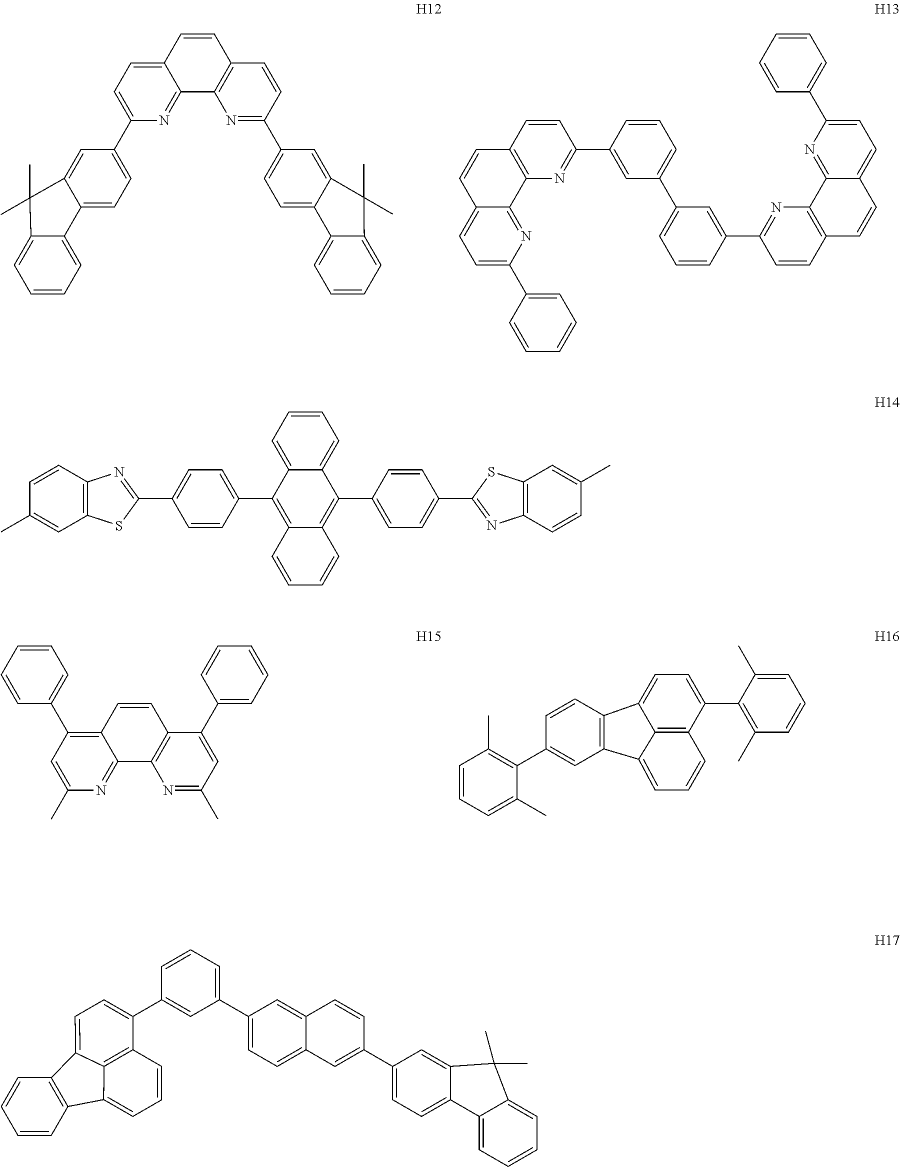

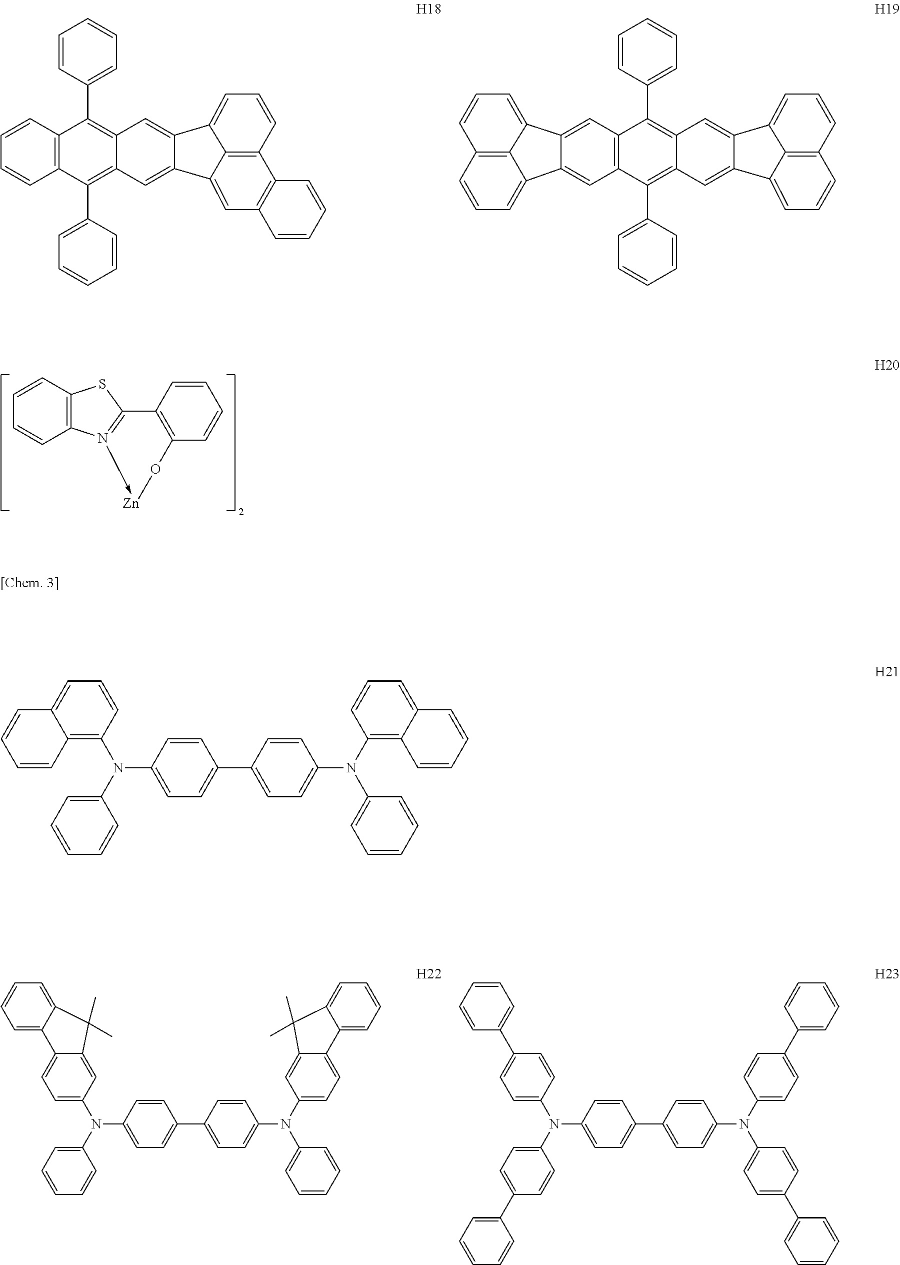

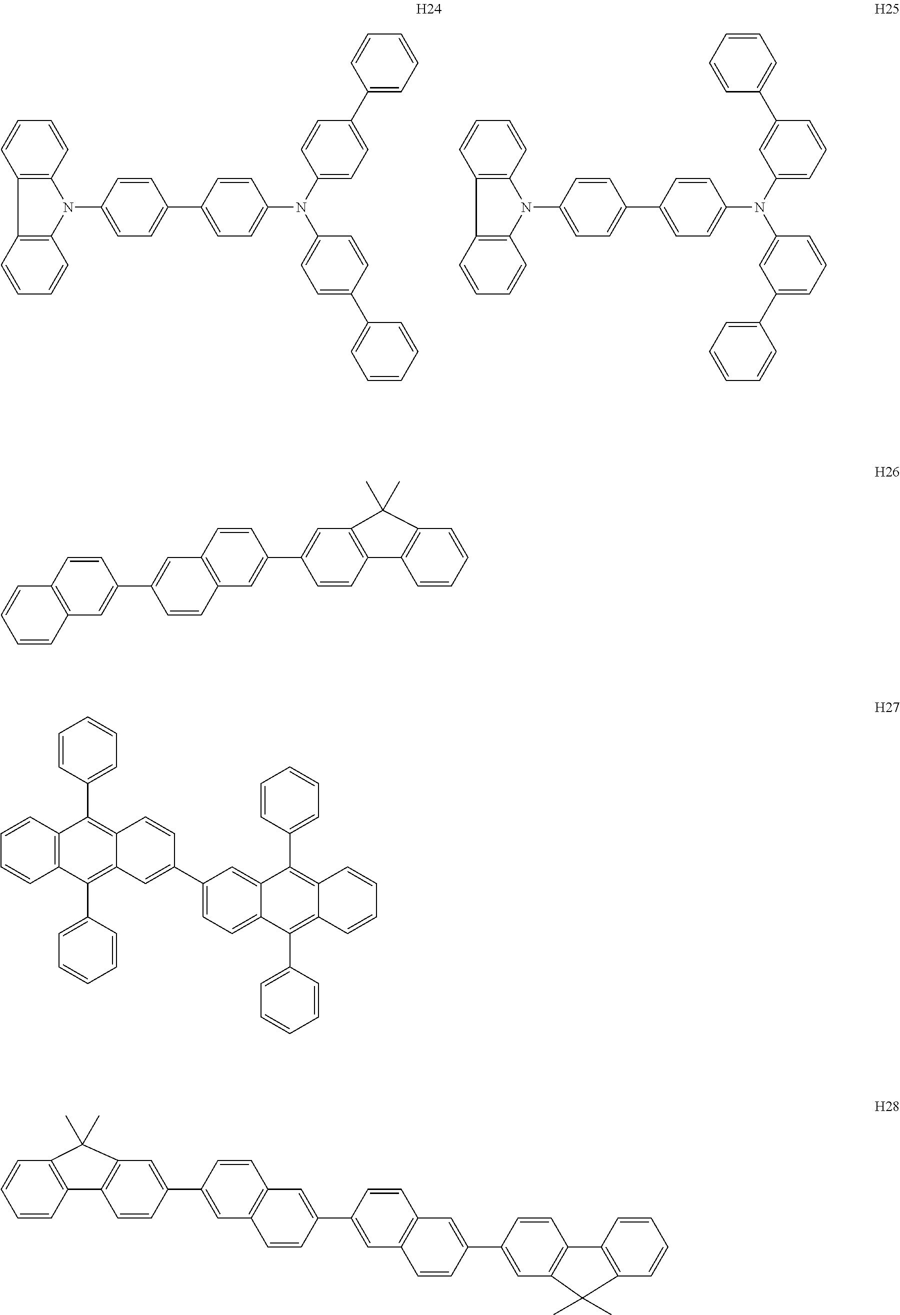

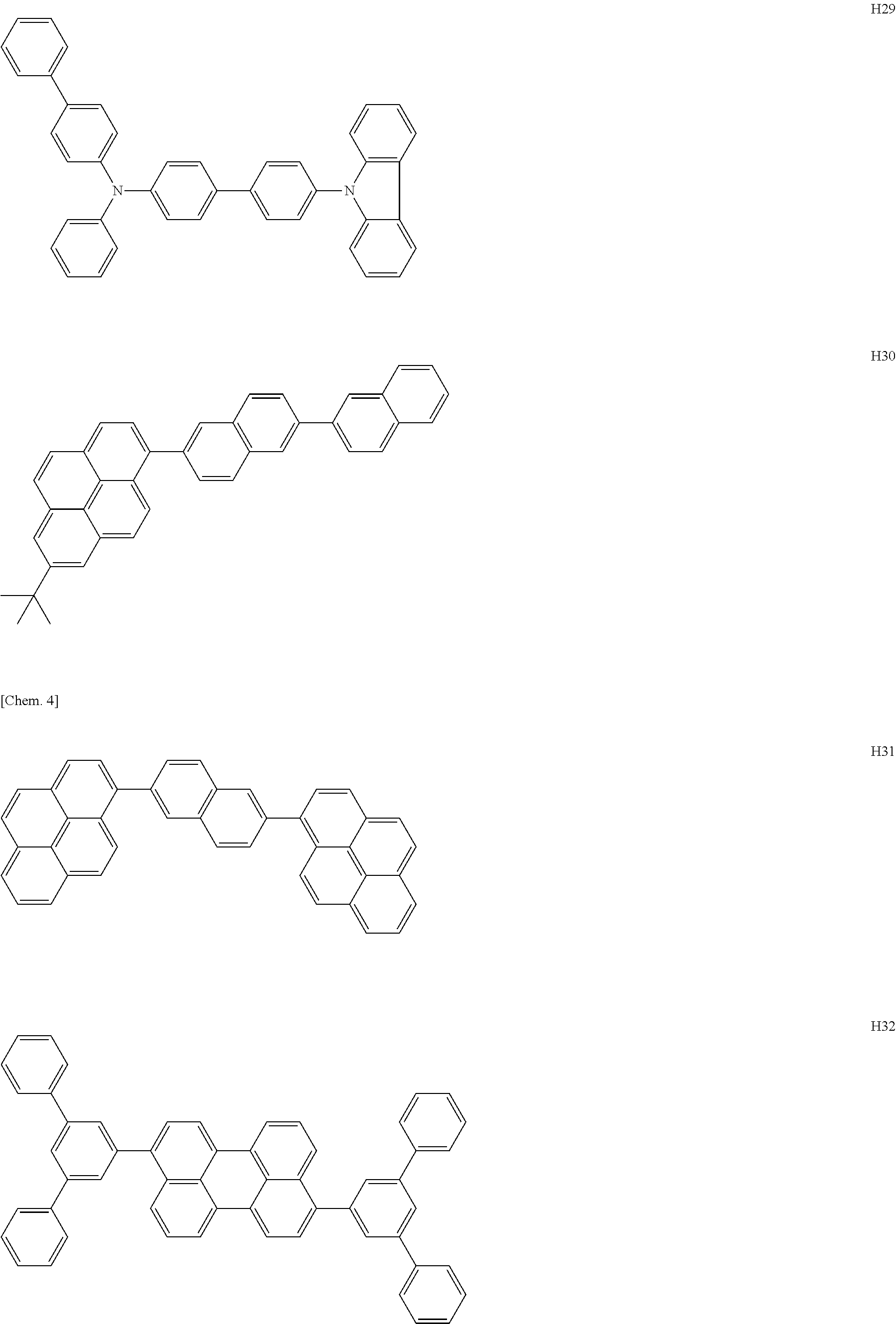

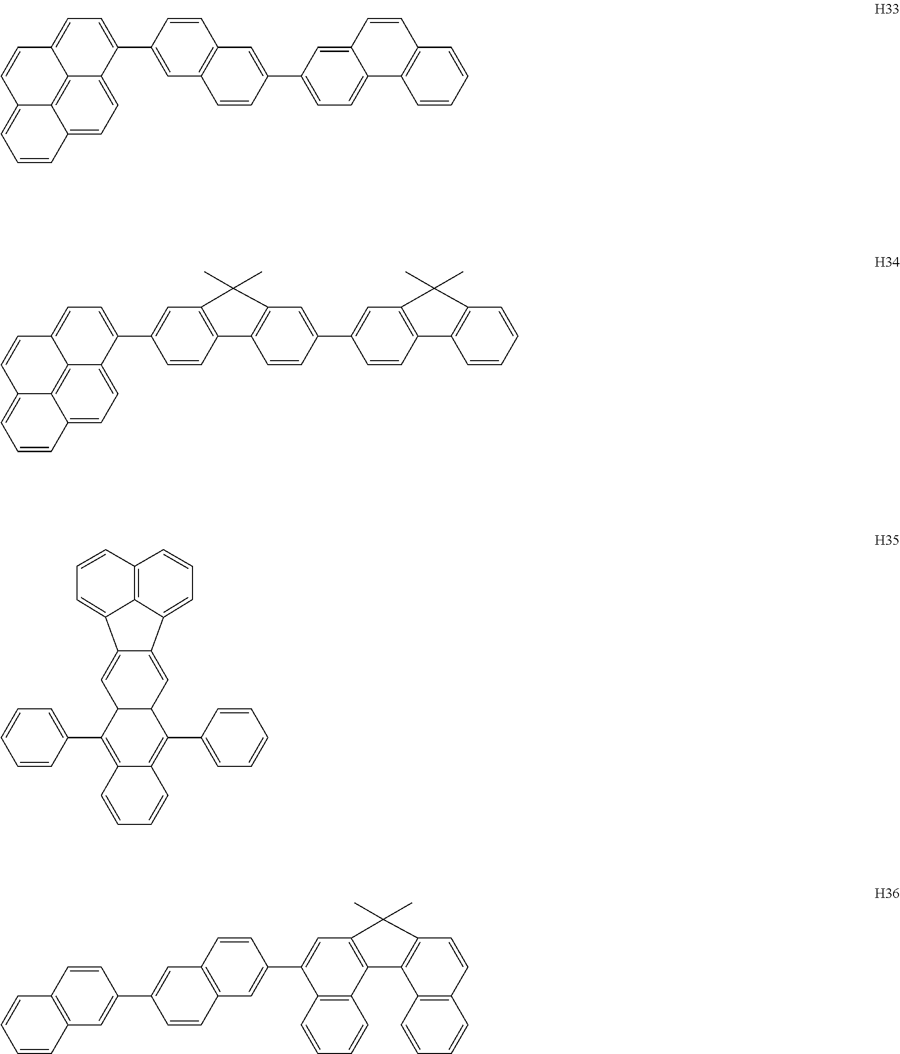

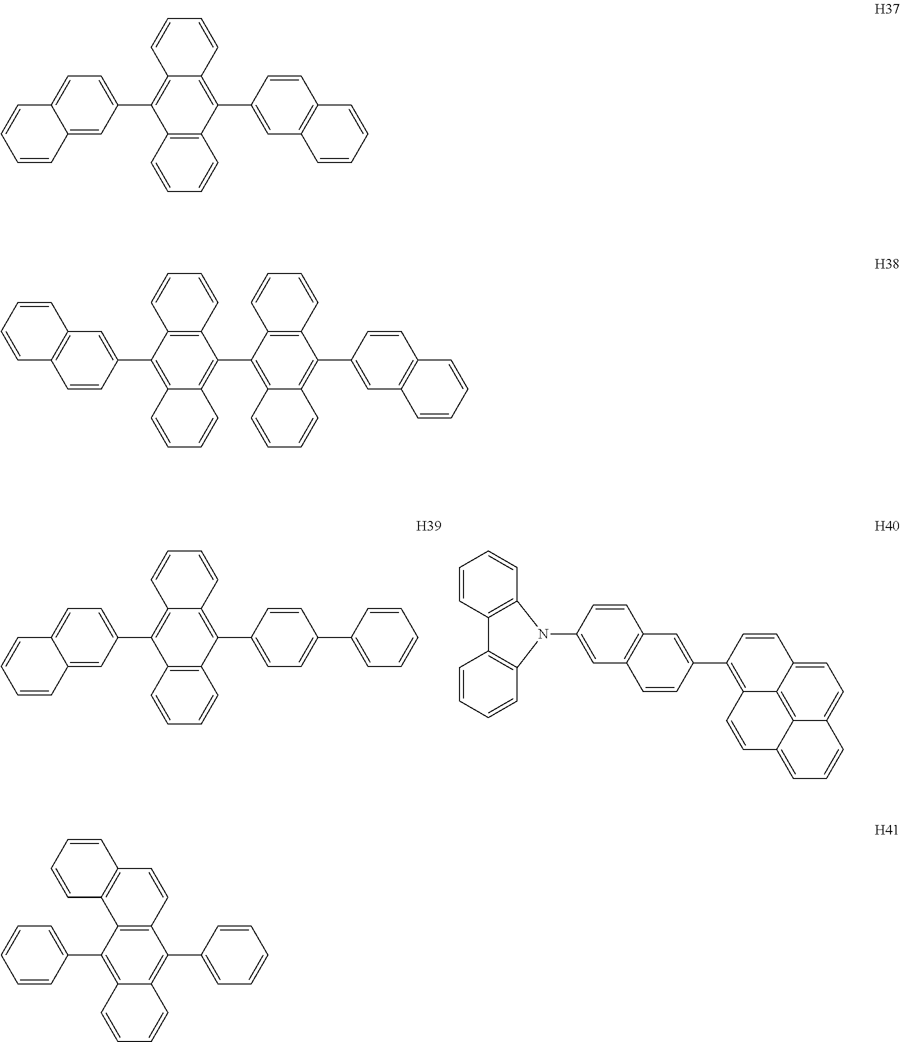

However, the present invention is not limited to these compounds. Derivatives of the compounds represented by Chem. 1 to Chem. 4 can also be used as the hosts. Besides these compounds, condensed ring compounds can be used. Examples thereof include fluorene derivatives, naphthalene derivatives, anthracene derivatives, pyrene derivatives, carbazole derivatives, quinoxaline derivatives, quinoline derivatives, organic aluminum complexes such as tris (8-quinolinolate) aluminum and the like, and organic zinc complexes. In addition, triphenylamine derivatives can be used.

For the first to third hosts, the same material or different materials may be used. When the same material is used, the driving voltage can be decreased because of no injection barrier between the light-emitting layers.

Examples of the B dopant used in the present invention include compounds described below. However, the present invention is not limited to these compounds.

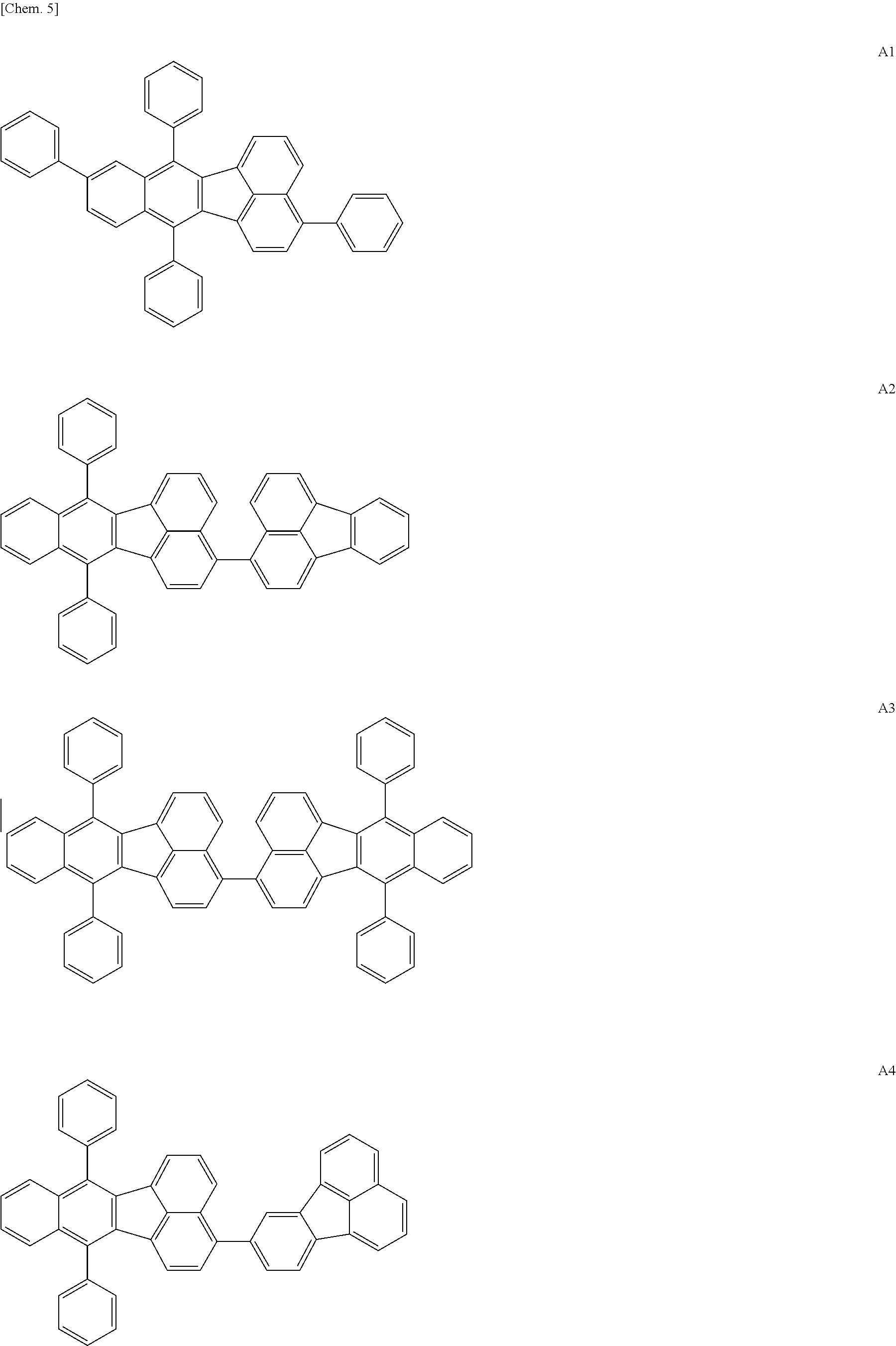

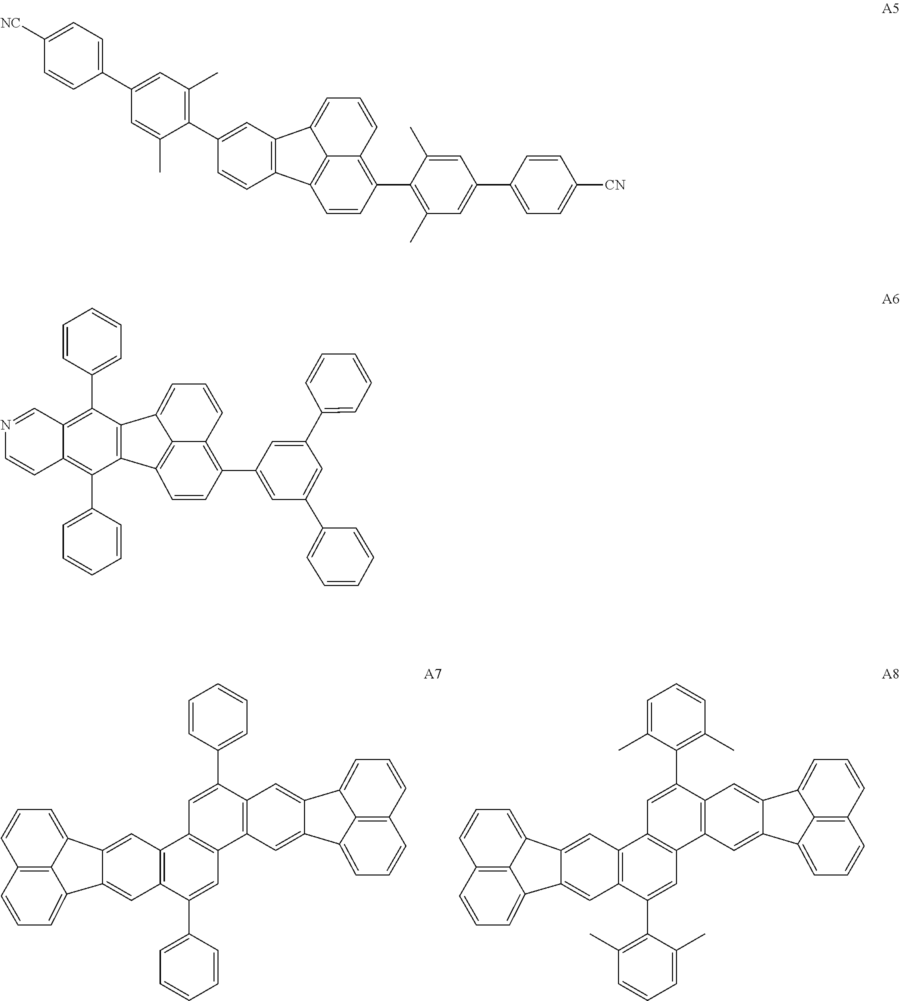

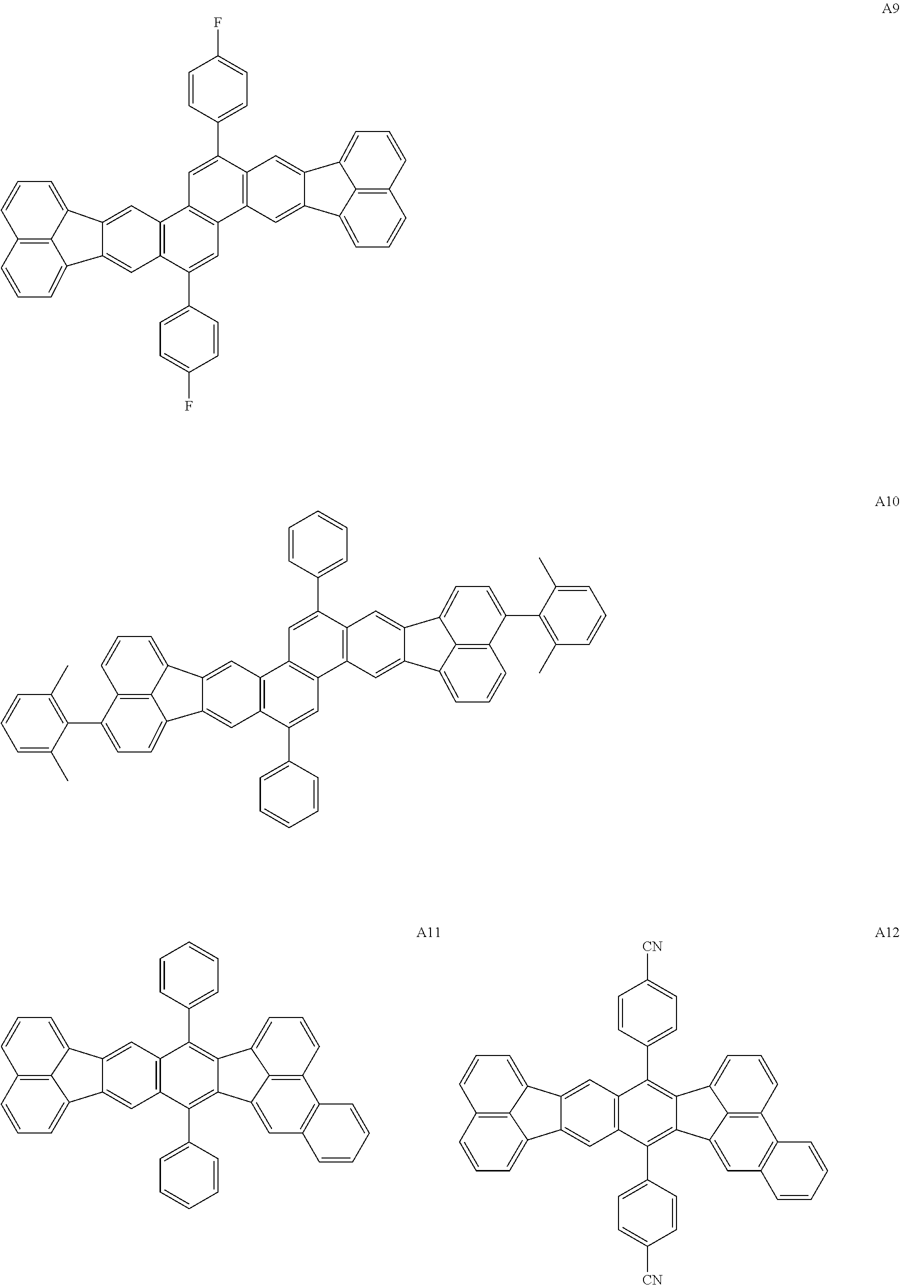

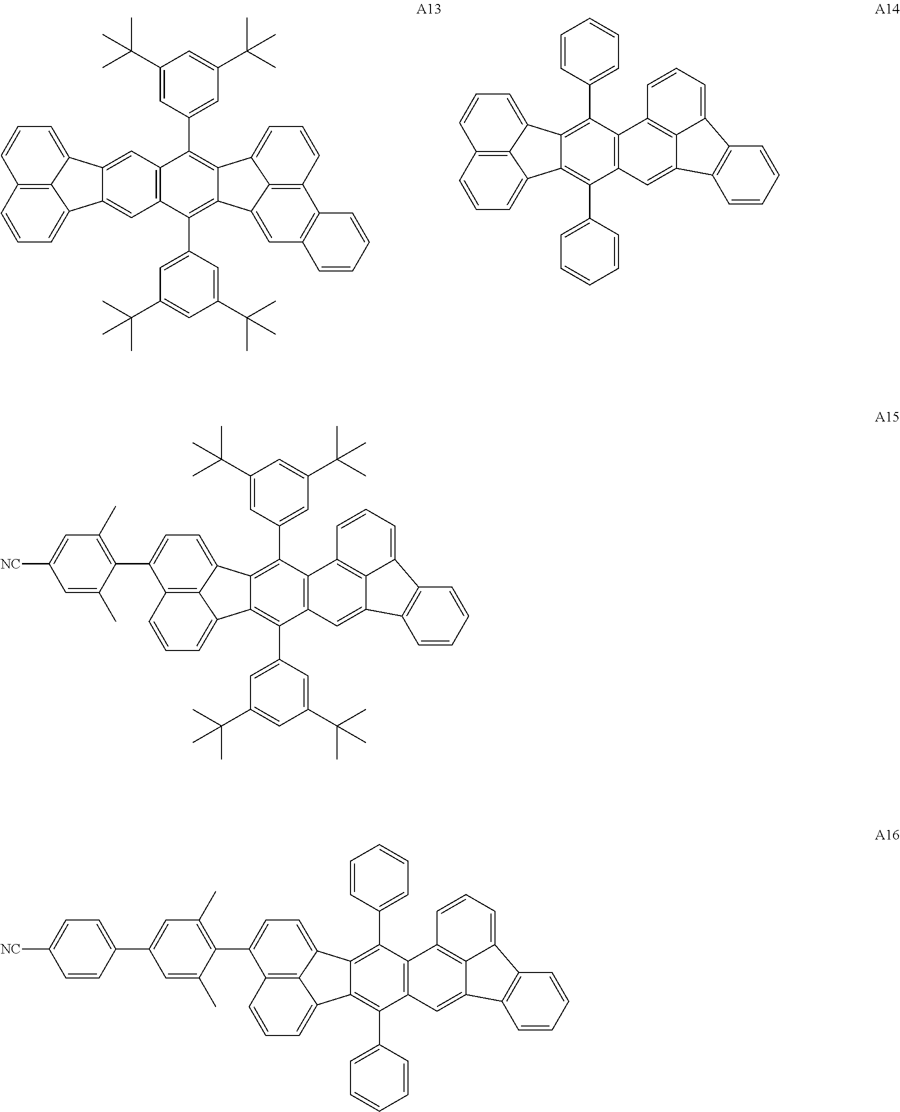

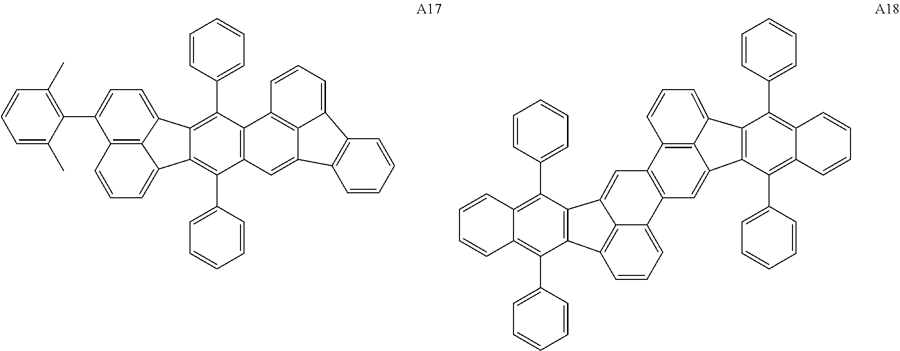

Examples of the G dopant used in the present invention include compounds described below. However, the present invention is not limited to these compounds.

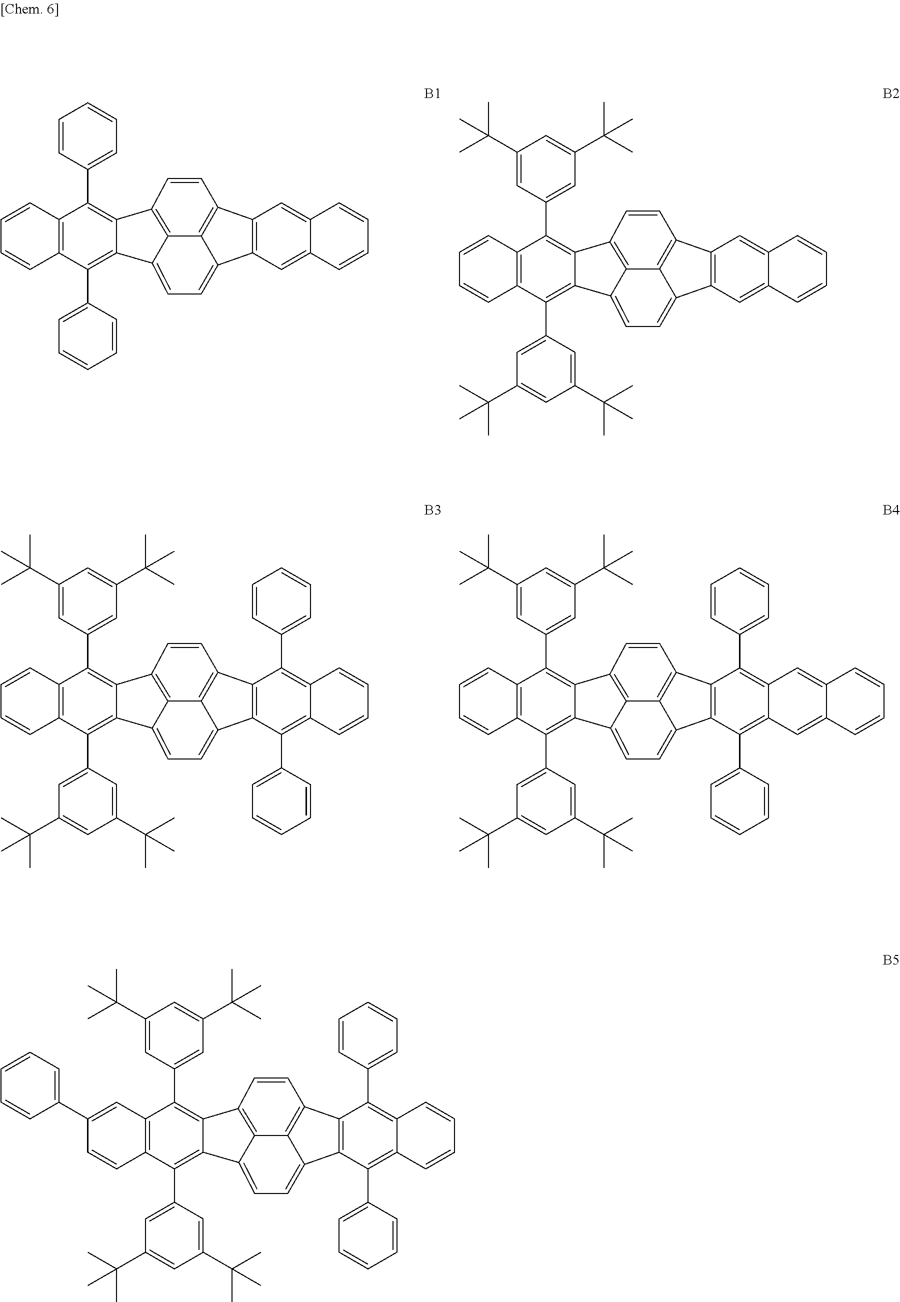

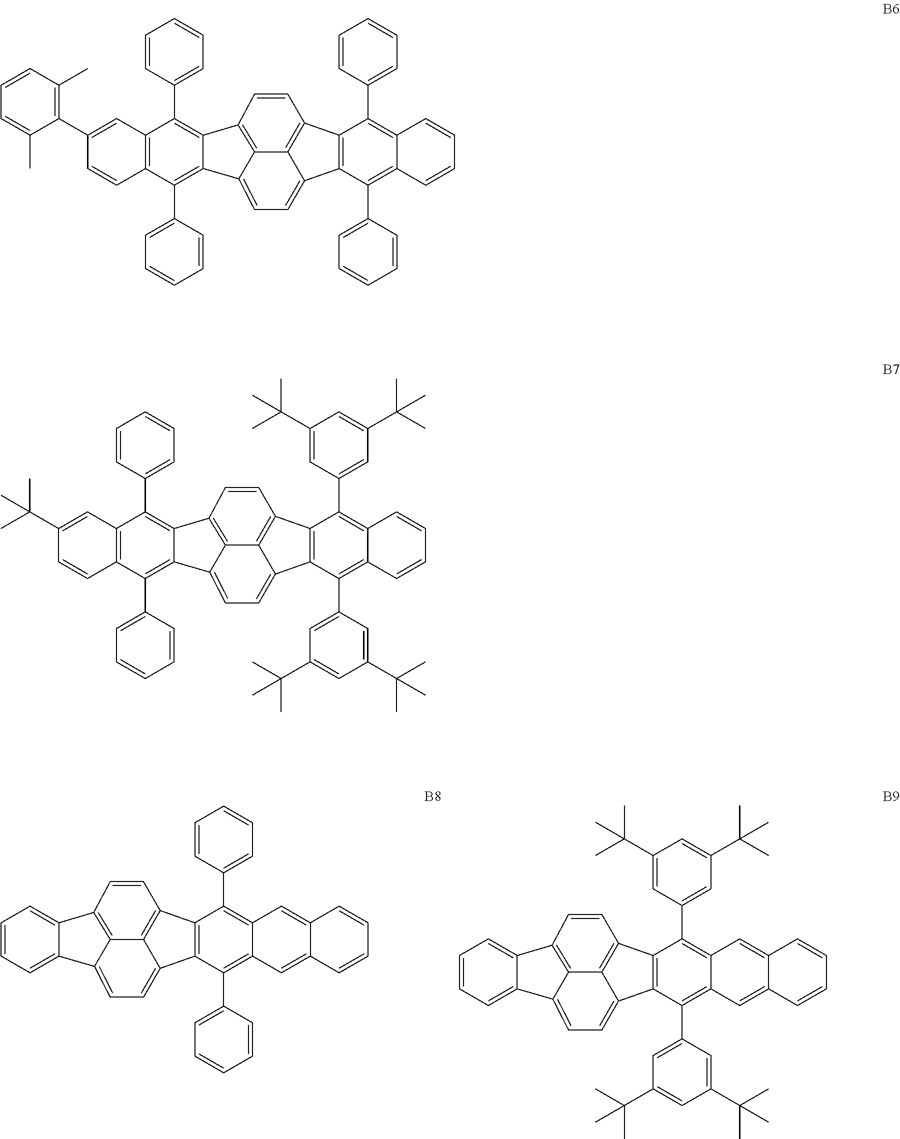

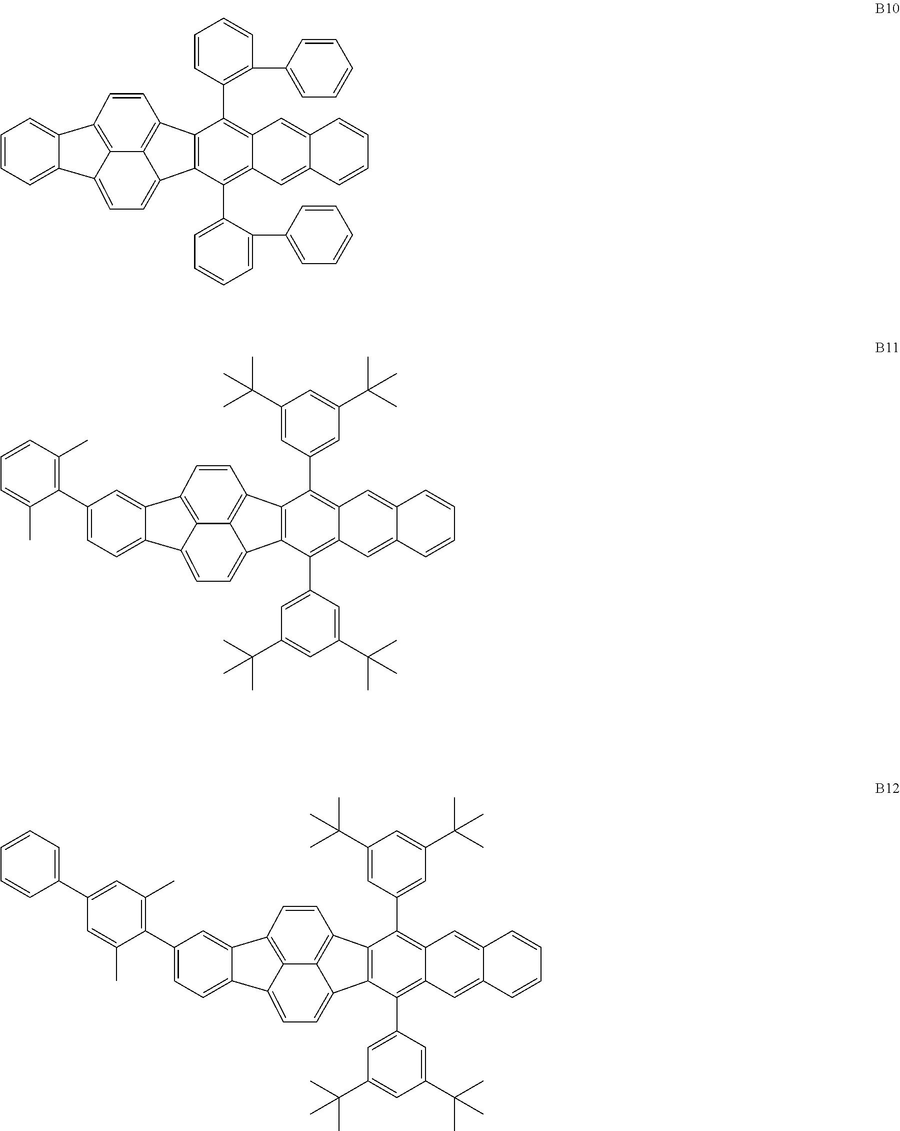

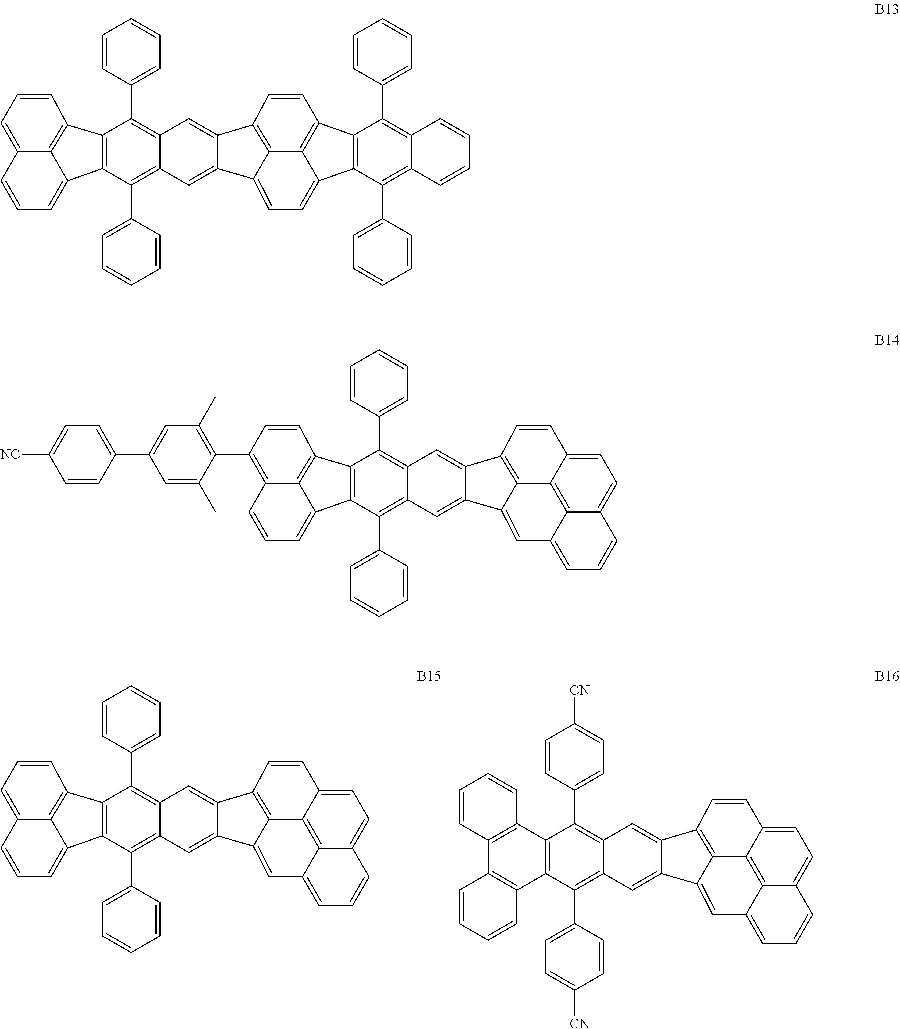

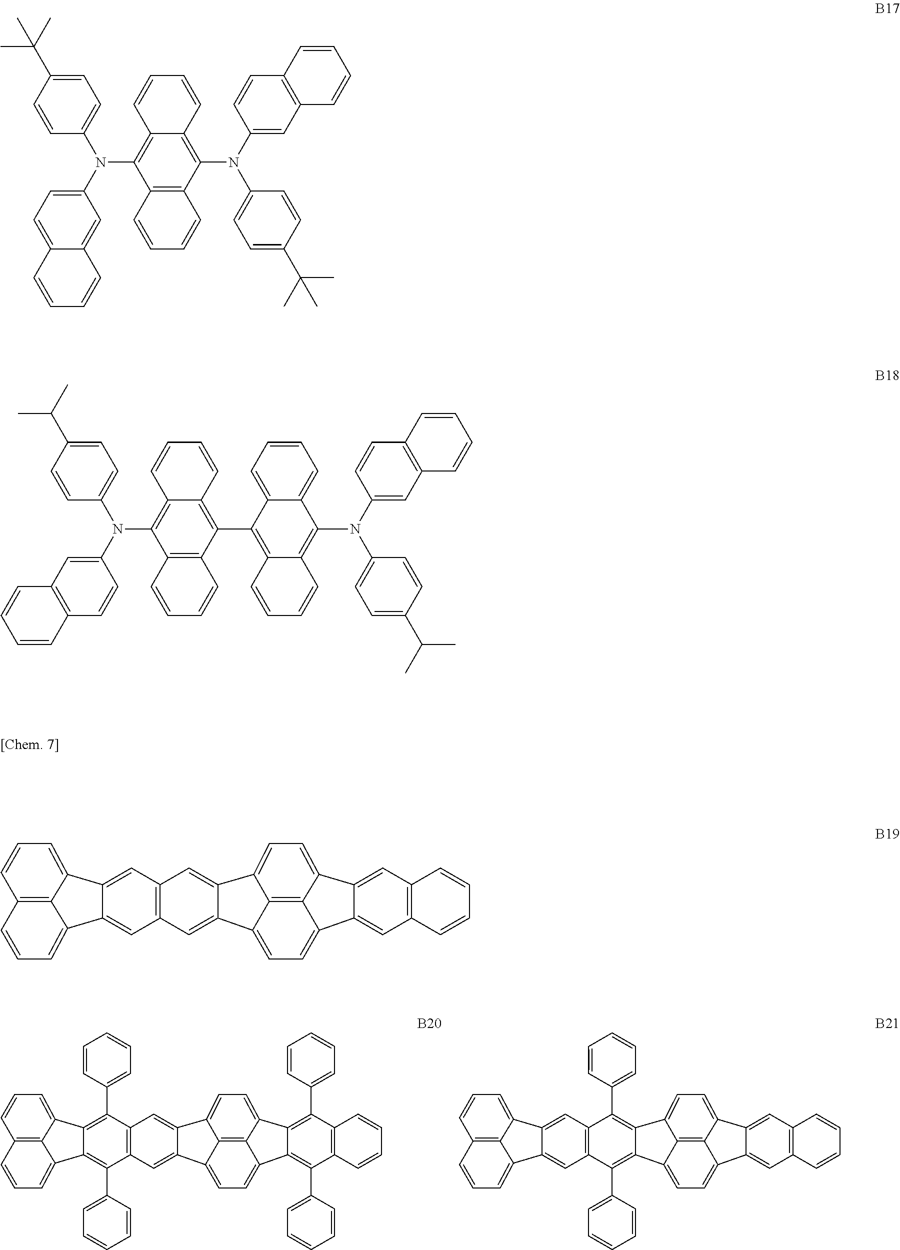

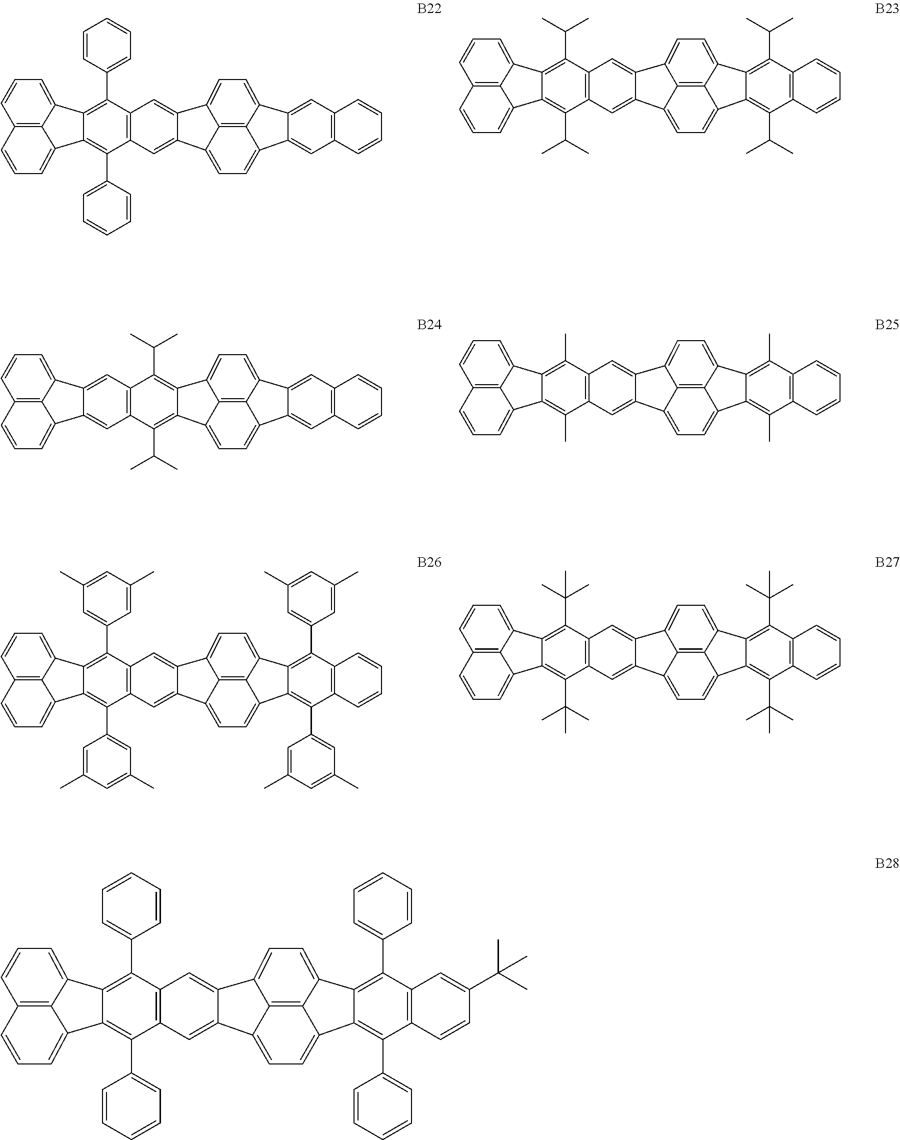

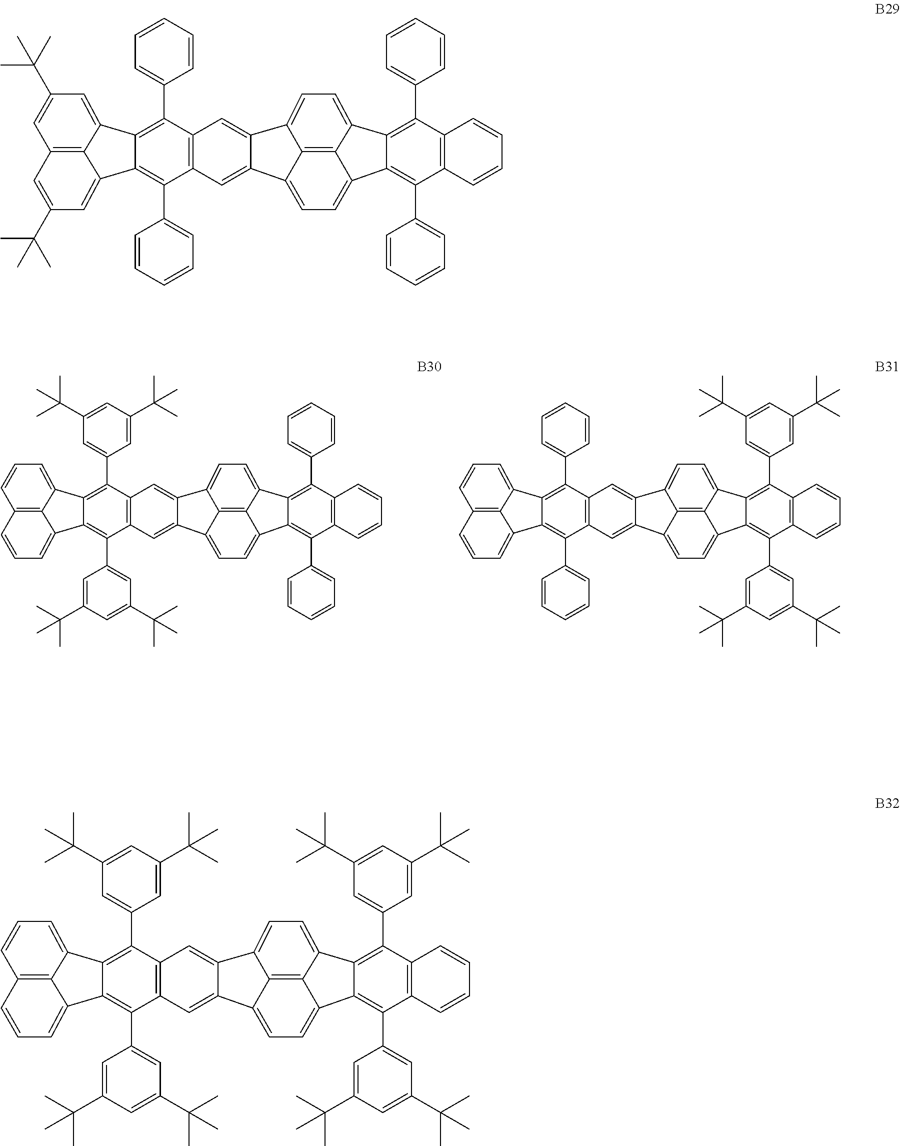

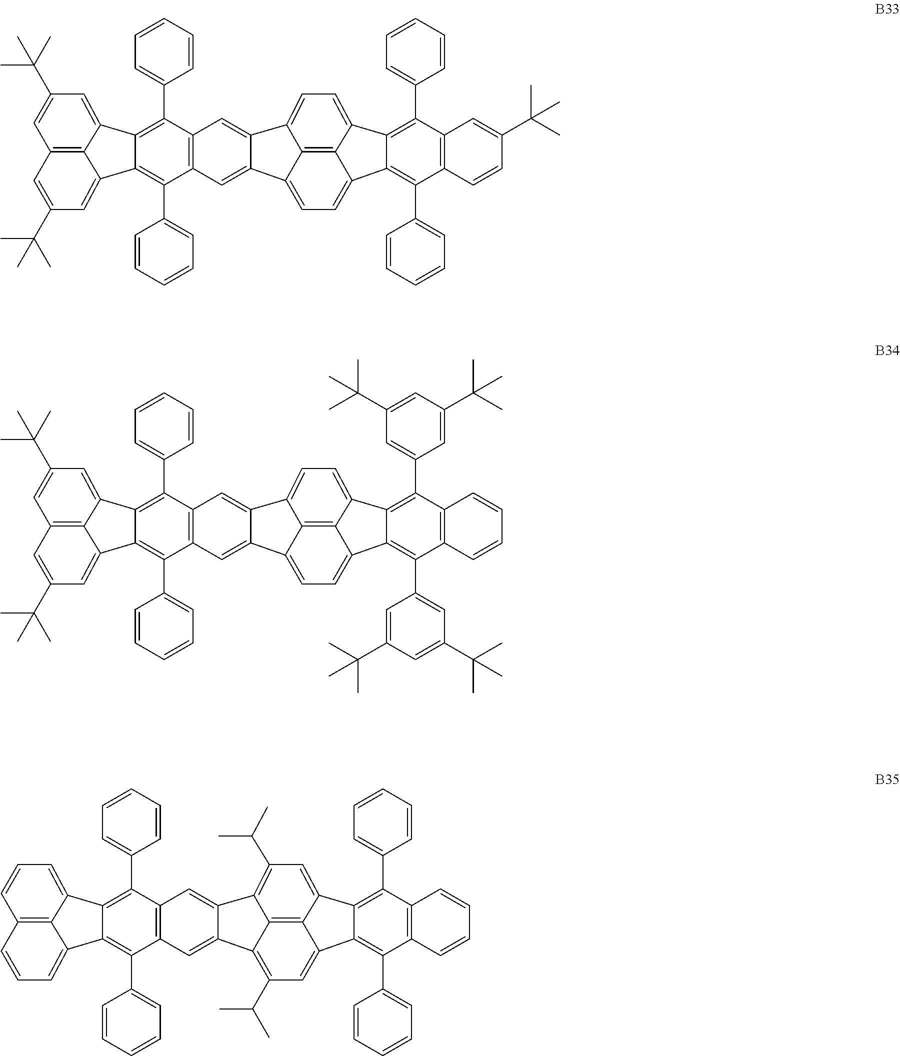

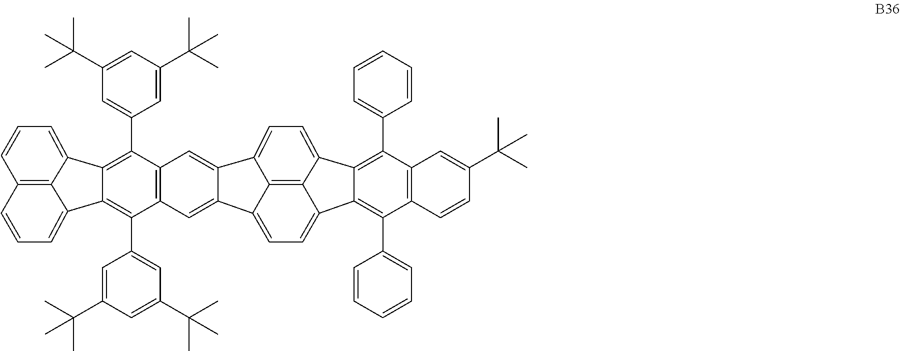 [SMILES: CC(C)(C)c1cc(-c2c3cc4c(cc3c(-c3cc(C(C)(C)C)cc(C(C)(C)C)c3)c3c5cccc6cccc(c23)c65)c2ccc3c5c(ccc4c52)-c2c-3c(-c3ccccc3)c3cc(C(C)(C)C)ccc3c2-c2ccccc2)cc(C(C)(C)C)c1]

Examples of the R dopant used in the present invention include compounds described below. However, the present invention is not limited to these compounds.

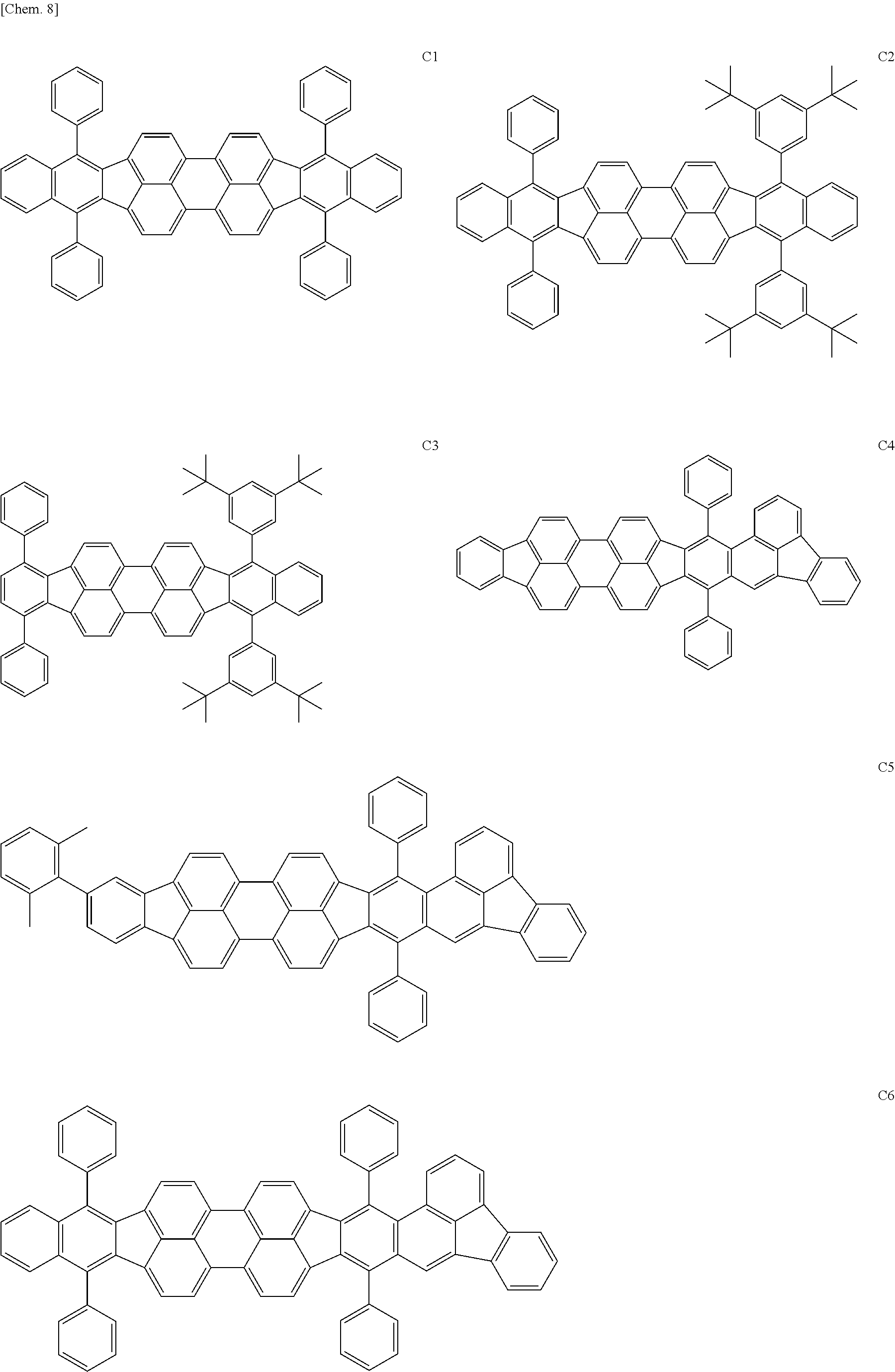

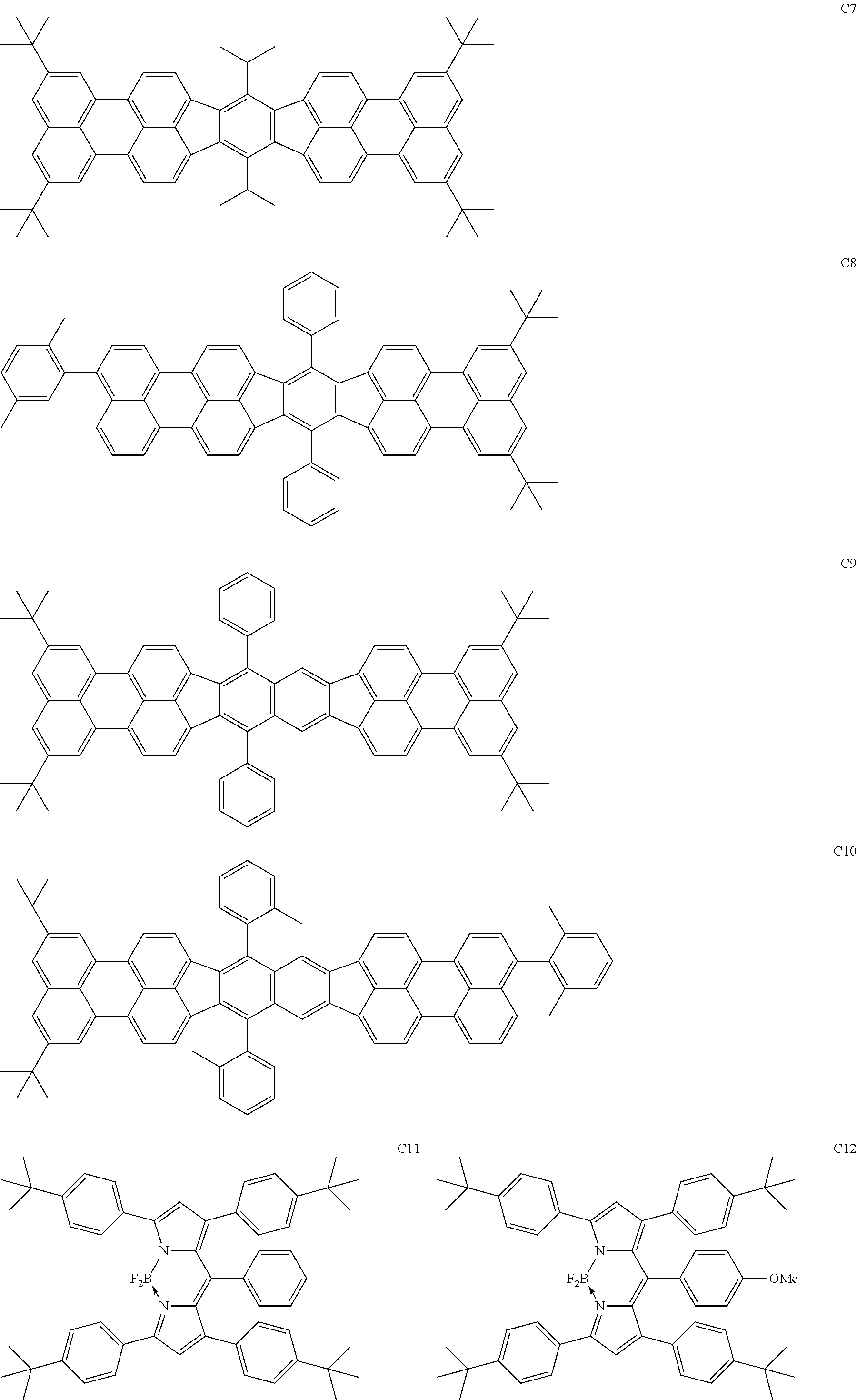

The doping concentration of each of the B and G dopants is preferably 0.1 to 10 percent by mass and more preferably 0.3 to 5 percent by mass. An excessively low concentration is undesired because the electron trapping probability is decreased to decrease the re-combination probability, resulting in a decrease in blue light emission intensity. Conversely, an excessively high concentration is undesired because concentration quenching occurs.

A method for synthesizing exemplified compounds B19 to B36 is described. These compounds are synthesized, for example, according to reaction formulae described below.

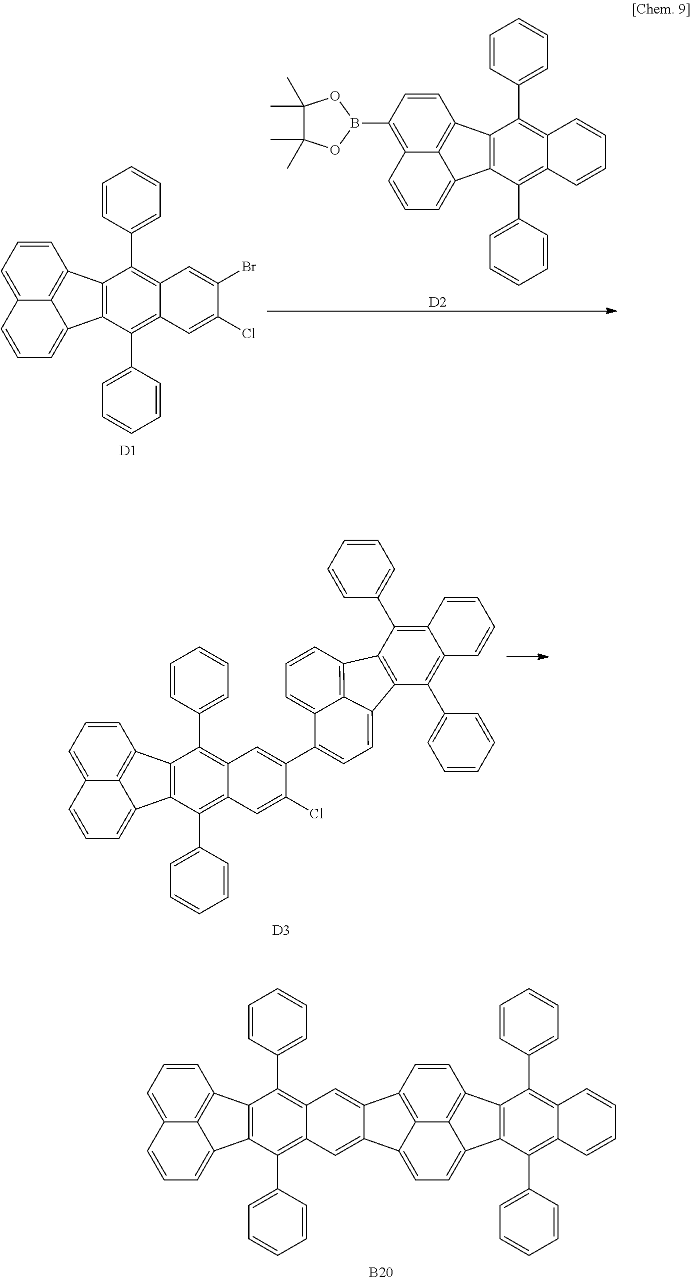

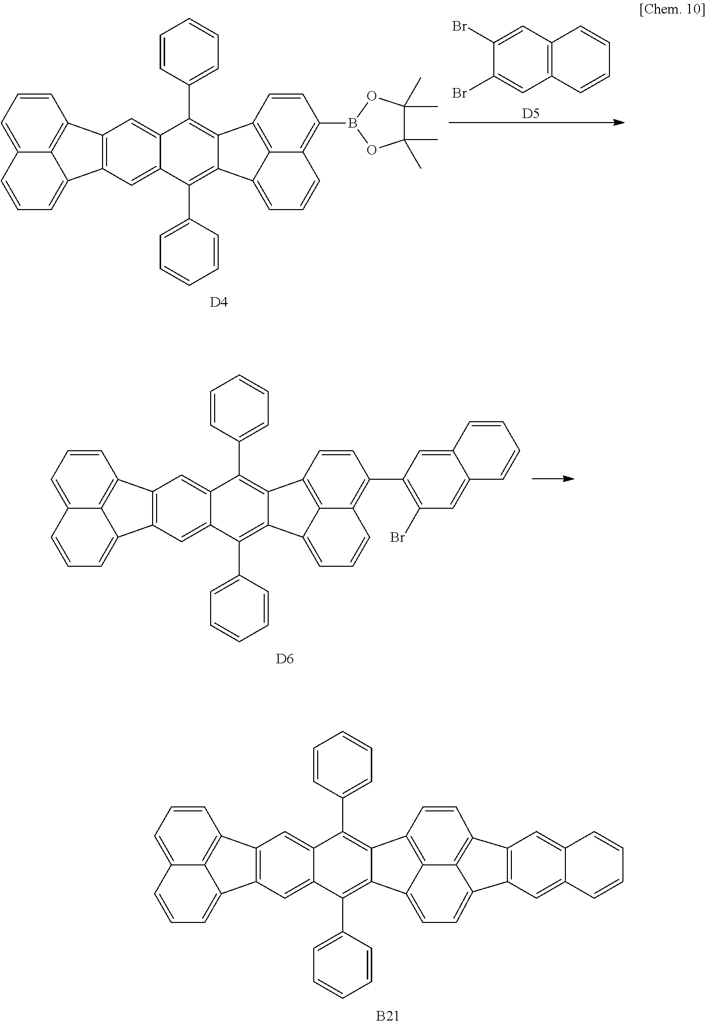

As shown by the reaction formulae, the exemplified compounds B20 and B21 are synthesized using compounds (a) to (d) described below as raw materials.

(a) Benzo[k] fluoranthene derivative (D1)
(b) Benzo[k] fluoranthene derivative (D2)
(c) Fluorantheno[8,9-k] fluoranthene derivative (D4)
(d) Naphthalene derivative (D5)

In addition, various compounds can be synthesized by changing D1 to D4 in the reaction formulae.

An example of a synthesis route for exemplified compound C4 is described. A reaction formula is shown below. When a substituent is introduced in the reaction formula, an intended compound can be synthesized by substituting a hydrogen atom at the introduction position with a substituent. Examples of the substituent include an alkyl group, a halogen atom, a phenyl group, and the like.

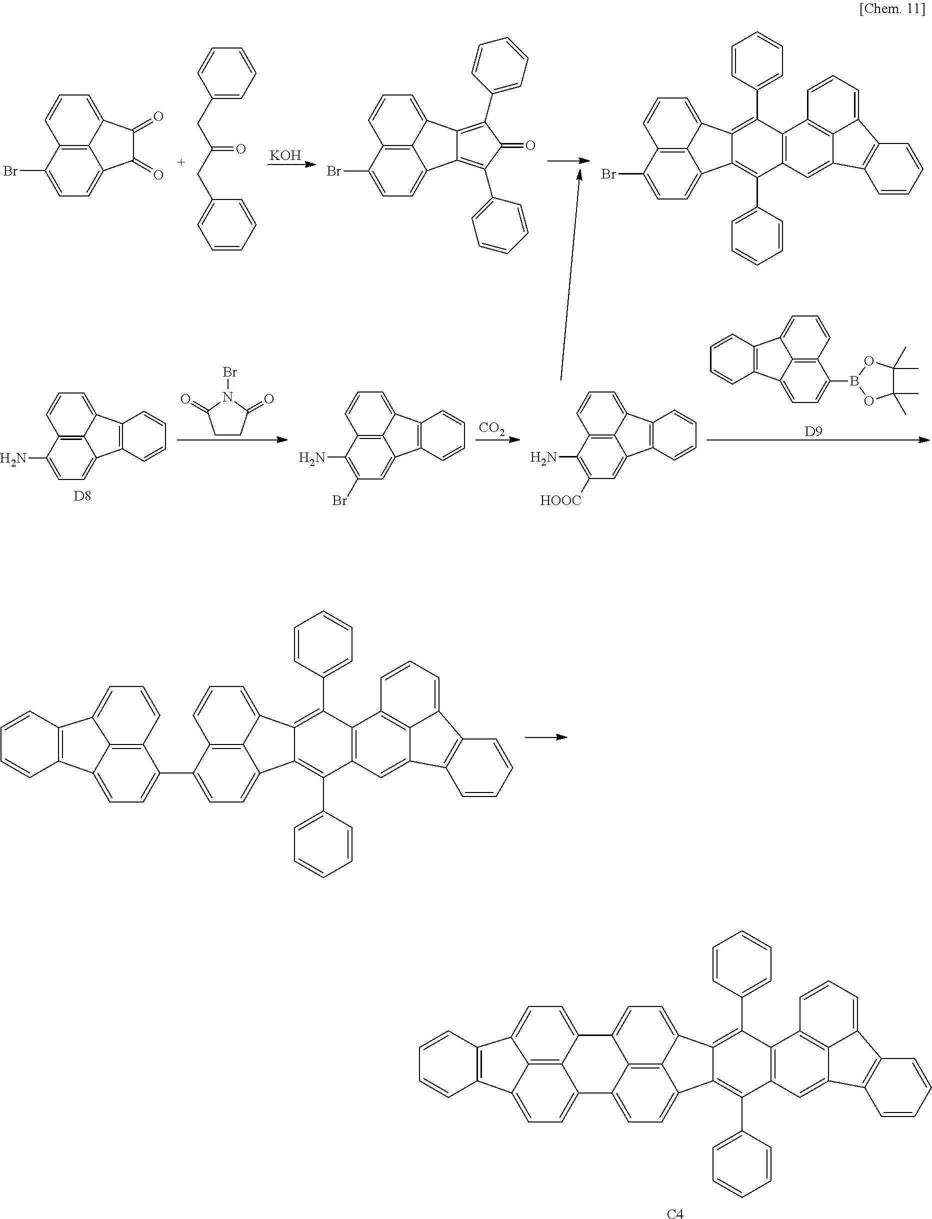

As shown in the reaction formula, the exemplified compound C4 is synthesized using compounds (e) to (g) described below as raw materials.

(e) Ketone derivative (D7)
(f) Fluoranthene derivative (D8)
(g) Fluoranthene derivative (D9)

A method for synthesizing exemplified compounds C9 and C10 is described. These compounds are synthesized, for example, according to a reaction formula described below.

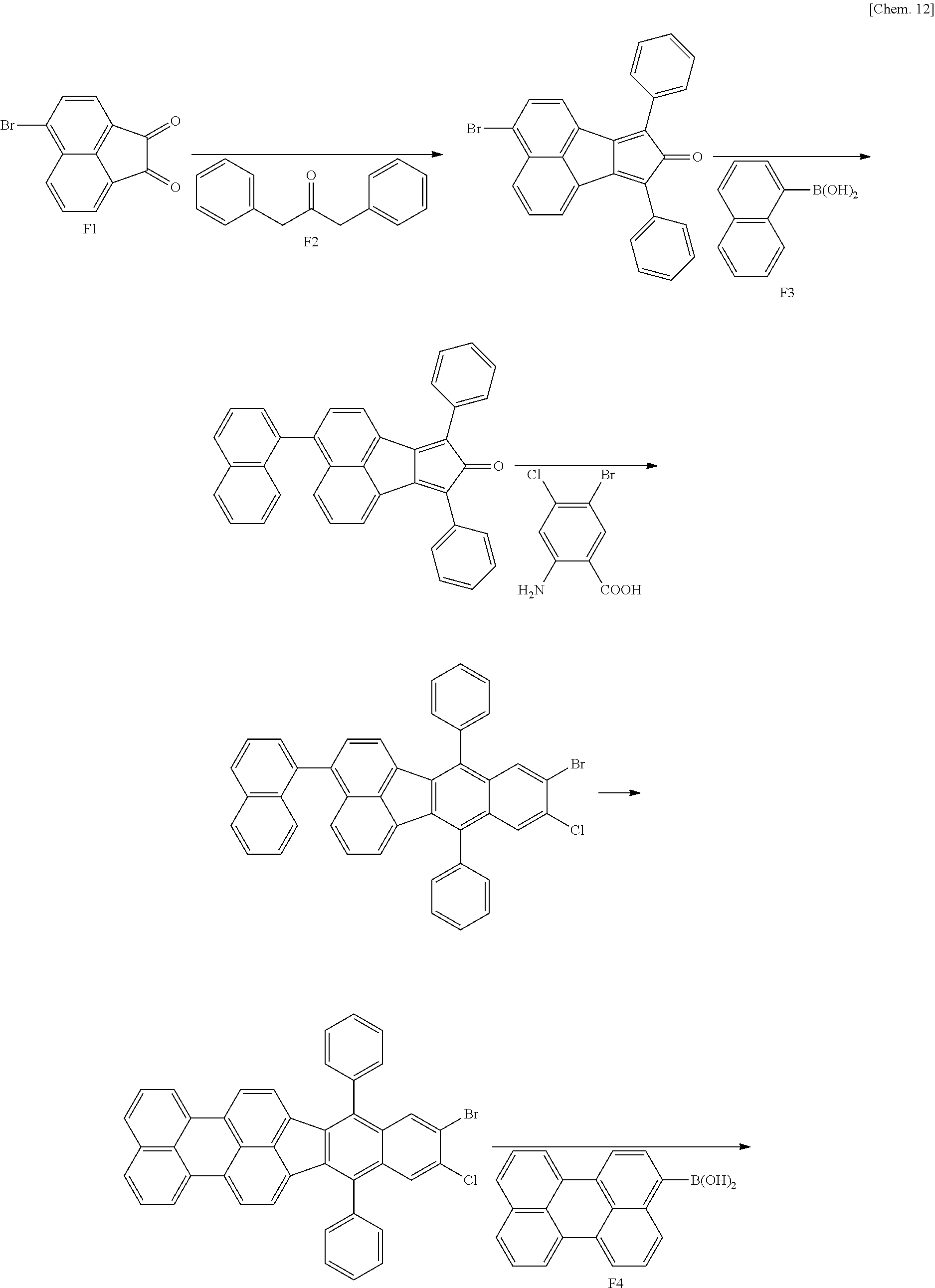

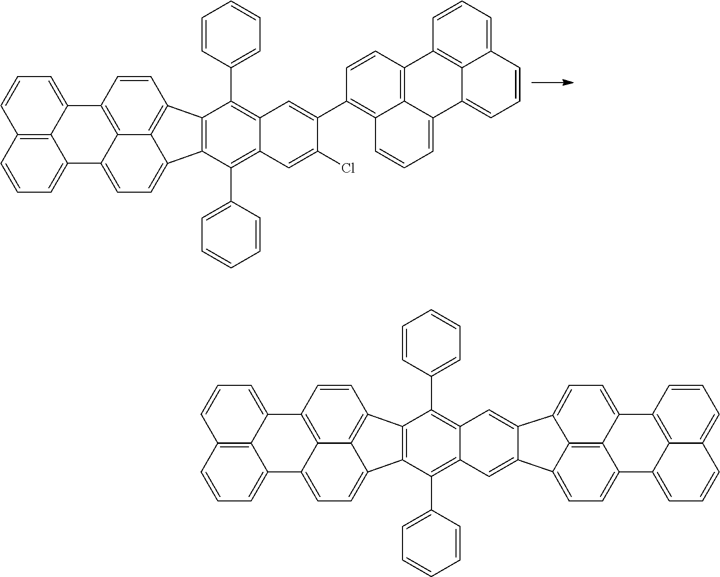

As shown in the reaction formula, the exemplified compounds are synthesized using compounds (h) to (k) described below as raw materials.

(h) Diketone derivative (F1)
(i) Dibenzylketone derivative (F2)
(j) Naphthalene derivative (F3)
(k) Binaphthyl derivative (F4)

In addition, exemplified compounds C9 and 10 can be synthesized by changing F1 to F4 in the reaction formula.

The other component members are described below.

As the substrate 1, any one of quartz, glass, a silicon wafer, a resin, and a metal may be used. In addition, a switching element such as a transistor and wiring (not shown) may be provided on the substrate 1, and an insulating layer (not shown) may be provided thereon. The insulating layer may be any layer as long as contact holes can be formed for securing electric conduction between the anode 2 and wiring (not shown) and securing insulation from unconnected wiring. For example, a resin such as polyimide, silicon oxide, silicon nitride, or the like can be used.

When the anode 2 is used as a reflecting electrode, for example, chromium, aluminum, silver, titanium, tungsten, molybdenum, or an alloy or laminate thereof can be used. When the anode 2 is used as a transparent electrode, an oxide transparent conductive layer of indium tin oxide (ITO), indium zinc oxide, or the like can be used. However, the anode 2 is not limited to these. The electrode can be formed using a known photolithographic technique.

A known material can be used for the hole transport layer 3. Examples thereof include, but are not limited to, triphenyldiamine derivatives, oxadiazole derivatives, porphyrin derivatives, stilbene derivatives, and the like. In addition, the function of the hole transport layer 3 may be carried out by a laminate of the hole injection layer 8 and the hole transport layer 3, i.e., a plurality of layers. For the hole injection layer 8, an oxide such as molybdenum oxide, tungsten oxide, or the like, an organic material such as 2,3,5,6-tetrafluoro-7,7,8,8-tetracyanoquinodimethane (F4TCNQ), or a mixed layer containing such a material and the hole transport layer 3 may be used. In particular, when a material such as F4TCNQ is mixed with the hole transport layer 3, a hole injection-transport layer with low resistance can be formed, thereby decreasing the driving voltage. The thickness of the hole transport layer 3 may be common to pixels or may be changed according to colors in order to adjust interference.

Further, an electron blocking layer (not shown) may be provided between the hole transport layer 3 and the second light-emitting layer 4 or the third light-emitting layer (not shown). By providing the electron blocking layer with a shallower LUMO than the hosts of the light-emitting layers, excitons can be effectively confined in the light-emitting layers, thereby increasing the efficiency.

A known material can be used for the electron transport layer 6. Examples thereof include, but are not limited to, aluminum quinolinol derivatives, oxadiazole derivatives, triazole derivative, phenylquinoxaline derivatives, silole derivatives, phenanthroline derivatives, and the like. The function of the electron transport layer 6 may be carried out by a laminate of an electron injection layer (not shown) and the electron transport layer 6, i.e., a plurality of layers.

For the electron injection layer, a mixture containing an electron-donating dopant and an electron-transporting material may be used. As the electron-donating dopant, an alkali metal, an alkaline-earth metal, a rare earth metal, and a compound thereof can be used. The electron injection layer is formed by mixing 0.1 to several tens percent by mass of an alkali metal compound with an electron-transporting material. A cesium compound can be used as the alkali metal compound, and cesium carbonate and a material derived from cesium carbonate can be used as the cesium compound. In the present invention, a method for forming the electron injection layer is to co-deposit cesium carbonate and the electron-transporting material. In order to secure the good electron injection property, the thickness of the electron injection layer is 10 nm to 100 nm. During co-deposition, cesium carbonate may be decomposed to form sub-oxides such as (Cs₁₁O₃)Cs₁₀, (Cs₁₁O₃)Cs, Cs₁₁O₃, etc., which are derived from cesium carbonate, in the electron injection layer. Also, a coordination compound may be formed between cesium and an organic compound.

In addition, a hole blocking layer (not shown) may be provided between the electron transport layer 6 and the first light-emitting layer 5. By providing the hole blocking layer with deeper HOMO than the host of the light-emitting layer, excitons can be effectively confined in the light-emitting layer, leading to improvement in efficiency.

The cathode 7 is not particularly limited and may be formed using an oxide conductive layer of ITO to form a top-emission element or using a reflective electrode of aluminum (Al) to form a bottom-emission element. A method for forming the cathode 7 is not particularly limited, but a direct-current or alternating-current sputtering method can be used in order to improve film coverage and easily decrease the resistance.

After the cathode 7 is formed, a sealing member (not shown) may be provided. For example, the entry of water etc. into the organic EL layer and the occurrence of display defect can be suppressed by bonding glass provided with a moisture absorbent to the substrate. In another embodiment, the entry of water etc. into the organic EL layer may be suppressed by providing a passivation film of silicon nitride or the like on the cathode 7. For example, after the cathode 7 is formed, the element may be transferred to another chamber without breakage of a vacuum, and a silicon nitride film having a thickness of 1 to 10 micrometers may be formed by a CVD method to form a sealing film.

In addition, a color filter may be provided in each of the pixels. For example, a color filter adjusted to the size of a pixel may be provided on another substrate, which is then bonded to the substrate on which the organic EL element has been provided, or a color filter may be patterned on a sealing film of silicon oxide or the like using a photolithographic technique.

In the organic EL element of the present invention, a layer containing an organic compound and a layer containing another organic compound can be formed by a method described below. In general, a thin film is formed by a vacuum vapor deposition method, an ionic vapor deposition method, sputtering, plasma, or a known coating method (for example, spin coating, dipping, casting, LB method, ink jet method, or the like) using a solution in a proper solvent. When the layer is formed by the vacuum deposition method or solution coating method, temporal stability is excellent with little crystallization or the like. When a film is formed by the coating method, the film can also be formed by combining a proper binder resin.

Examples of the binder resin include polyvinylcarbazole resins, polycarbonate resins, polyester resins, ABS resins, acryl resins, polyimide resins, phenol resins, epoxy resins, silicone resins, urea resins, and the like. However, the binder resin is not limited to these resins. In addition, these binder resins may be used alone as a homopolymer or copolymer or used as a mixture of two or more. Further, if required, additives such as a known plasticizer, antioxidant, ultraviolet absorber, etc, may be combined with the resin.

The organic EL element of the present invention can be used as a component member of a display apparatus and an illuminating apparatus. Other uses include an exposure light source of an electrophotographic image forming apparatus, a backlight of a liquid crystal display apparatus, a white light source using a color filter, and the like. An example of the color filter is a filter which transmits lights of three colors including red, green, and blue.

The display apparatus includes the organic EL element of the present invention in a display portion. The display portion includes a plurality of pixels. Each of the pixels includes the organic EL element of the present invention and TFT as an example of a switching element for controlling luminance, the anode or cathode of the organic EL element being connected to a drain electrode or source electrode of the TFT. The display apparatus can be used as an image display apparatus of PC or the like.

The display apparatus may be an image input apparatus including an input portion which inputs image information from area CCD (Charge Coupled Device), linear CCD, a memory card, or the like, and outputs an input image to a display portion.

In addition, a display portion possessed by an imaging apparatus or an ink jet printer may have both the image output function of displaying image information input from the outside and the input function as an operation panel of inputting processed information to an image. Also, the display apparatus may be used in a display portion of a multi-function printer.

The illuminating apparatus is an apparatus which illuminates a room. The illuminating apparatus may emit light of any of the colors, i.e., white, natural white, other colors of blue to red. The illuminating apparatus includes the organic EL element of the present invention and a converter circuit connected to the element. The converter circuit is a circuit which converts an alternating-current voltage to a direct-current voltage. In addition, “white” represents light with a color temperature of 4200 K, and “natural white” represents light with a color temperature of 5000 K. The illuminating apparatus may include a color filter.

Next, a display apparatus using the organic EL element of the present invention is described below with reference to FIG. 2. FIG. 2 is a schematic sectional view of a display apparatus including the organic EL element of the present invention and TFT (Thin-Film Transistor) connected thereto.

The display apparatus also includes a substrate 10 of glass or the like and a moisture-proof film 11 provided on the substrate 10 in order to protect the TFT or an organic EL layer. Reference numeral 12 denotes a metal gate electrode, reference numeral 13 denotes a gate insulting film, and reference numeral 14 denotes a semiconductor layer. The TFT 17 has the semiconductor layer 14, a drain electrode 15, and a source electrode 16. Further, an insulating film 18 is provided on the TFT 17. An anode 20 of the organic light-emitting element is connected to the source electrode 16 through a contact hole 19.

The display apparatus according to the embodiment is not limited to this configuration as long as the anode or the cathode is connected to the source electrode or the drain electrode of the TFT 17. In addition, a first protecting layer 23 and a second protecting layer 24 are provided on a cathode 22 in order to suppress deterioration in the organic EL element.

When the display apparatus according to the embodiment is a display apparatus which emits white light, a light-emitting layer in an organic EL layer 21 shown in FIG. 2 is formed as laminated light-emitting layers shown in FIG. 1.

The organic EL element according to the embodiment includes the TFT as an example of a switching element, which controls luminance, and an image can be displayed based on luminance of each of a plurality of organic EL elements provided in a plane. The switching element according to the embodiment is not limited to the TFT, and it may be a transistor, a MIM (Metal Insulator Metal) element, or an active matrix driver formed on a substrate such as a Si substrate. The expression “on a substrate” includes “inside a substrate”. This is selected according to definition, and, for example, in the case of definition of about QVGA (320*240 pixels per inch), the organic EL element can be provided on the Si substrate. Drive of the display apparatus using the organic EL element according to the embodiment permits a stable display with good image quality for a long time.

The organic EL element of the present invention can be used for various displays. The displays include image display apparatuses such as display portions of a television and a personal computer, and display portions mounted on electronic apparatuses. The display portions mounted on electronic apparatuses include an in-car display portion, an image display portion of a digital camera, and operation panels of business equipment such as a copying machine and a laser beam printer. The organic EL element can also be used for illumination.

### EXAMPLES

### Example 1

Synthesis of exemplified compound B20: The exemplified compound B20 was synthesized according to a reaction formula below.

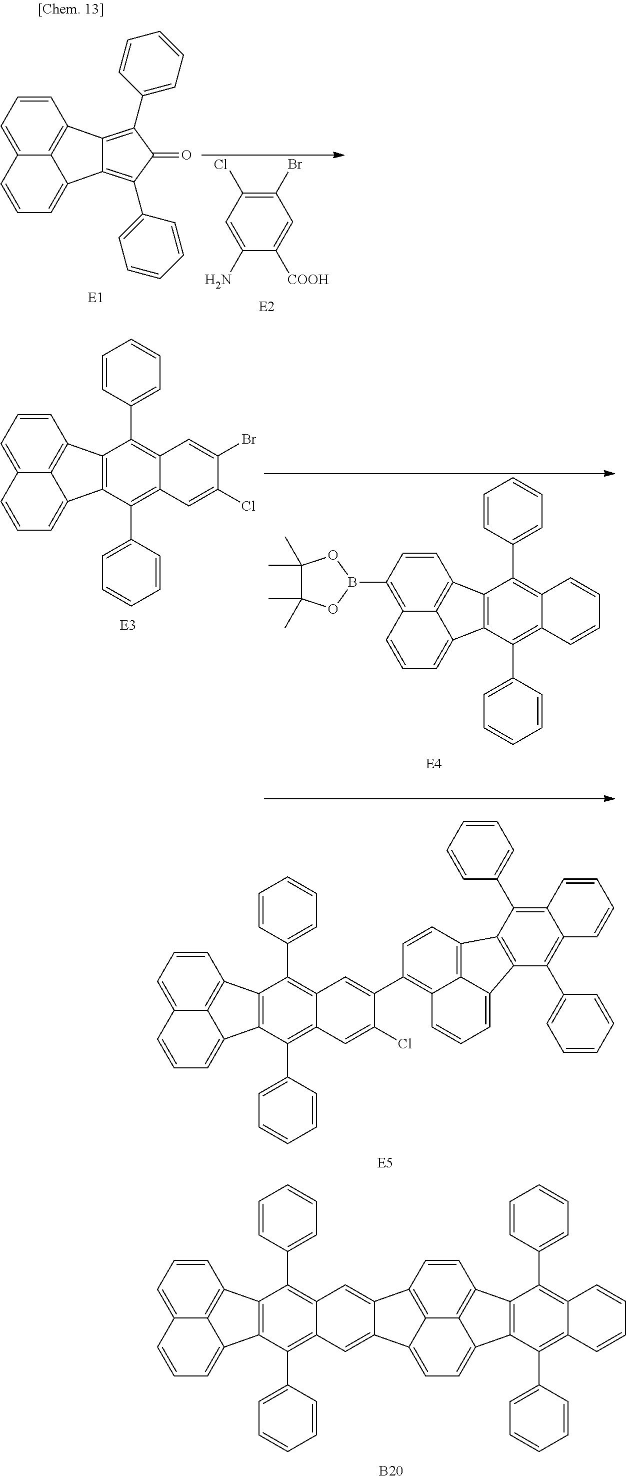

### (1) Synthesis of Compound E3

Reagents and a solvent described below were charged in a 100-ml eggplant type flask.

Compound E1: 3.56 g (10 mmol)
Compound E2: 3.25 g (13 mmol)
Isoamyl nitrite: 1.52 g (13 mmol)

### Toluene: 50 ml

Next, the reaction solution was heated to 110 degrees Celsius in a nitrogen stream and stirred at this temperature (110 degrees Celsius) for 3 hours. After the completion of reaction, the reaction solution was washed with 50 ml of water two times. The organic layer was washed with saturated saline, dried with magnesium sulfate, and then filtered. Then, the filtrate was concentrated to produce a brownish-red liquid. The resultant liquid was purified by column chromatography (chloroform/heptane=1:4) and then recrystallized with chloroform/methanol to yield 4.3 g of yellow crystal of E3 (yield: 83 percent).

### (2) Synthesis of Compound E5

Reagents and solvents described below were charged in a 200-ml eggplant type flask.

Compound E3: 2.59 g (5 mmol)
Compound E4: 2.65 g (5 mmol)

### Pd(PPh₂)₄: 0.1 g

### Toluene: 50 ml

### Ethanol: 20 ml

2M-aqueous sodium carbonate solution: 50 ml

Next, the reaction solution was heated to 80 degrees Celsius in a nitrogen stream and stirred at this temperature (80 degrees Celsius) for 8 hours. After the completion of reaction, ethanol was added to the solution to precipitate crystals, and then the crystals were filtered off and dispersed and washed in order with water, ethanol, and heptane. Next, the resultant crystals were dissolved in toluene under heating, purified by column chromatography (toluene/heptane=1:3), and then recrystallized with chloroform/methanol to yield 3.28 g of yellow compound E5 (yield: 78 percent).

### (3) Synthesis of Exemplified Compound B20

Reagents and a solvent described below were charged in a 20-ml eggplant type flask.

Compound E5: 841 mg (1 mmol)

### Pd(dba)₂: 238 mg

P(Cy)₃ (tricyclohexylphosphine): 280 mg
DBU (diazabicycloundecene): 0.15 ml

### DMF: 5 ml

Next, the reaction solution was heated to 145 degrees Celsius in a nitrogen stream and stirred at this temperature (145 degrees Celsius) for 6 hours. After the completion of reaction, ethanol was added to the solution to precipitate crystals, and then the crystals were filtered off and dispersed and washed in order with water, ethanol, and heptane. Next, the resultant purple crystals were dissolved in toluene under heating, hot-filtered, and then recrystallized with toluene/methanol to yield 0.60 g of orange exemplified compound B20 (yield: 75 percent).

The purity of this compound was confirmed to be 99 percent or more by HPLC (High Performance Liquid Chromatography). As a result of measurement of a photoluminescence emission spectrum of a 1*10⁻⁵ mol/L toluene solution of exemplified compound B20 at an excitation wavelength of 350 nm using Hitachi F-4500, a spectrum having a peak intensity at 512 nm was obtained. In addition, mass spectrometry of the exemplified compound B20 was performed with MALDI-TOF-MS (Autoflex LRF manufactured by Bruker Co., Ltd.).

### (MALDI-TOF-MS)

Measured value: m/z=804.11
Calculated value: C₆₄H₃₆=804.28

### Example 2

Synthesis of exemplified compound B30: The exemplified compound B30 was synthesized by the same method as in Example 1 except that compound E12 below was used in place of compound E1 used in Example 1(1).

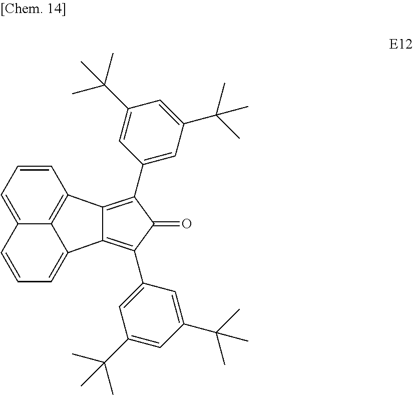 [SMILES: CC(C)(C)c1cc(C2=C3C(=C(c4cc(C(C)(C)C)cc(C(C)(C)C)c4)C2=O)c2cccc4cccc3c24)cc(C(C)(C)C)c1]

Evaluation of the purity of this compound by HPLC confirmed that the purity was 99 percent or more. As a result of measurement of an emission spectrum of a toluene solution (concentration: 1*10⁻⁵ mol/L) of exemplified compound B30 by the same method as in Example 1, a spectrum having a peak intensity at 515 nm was obtained. In addition, mass spectrometry was performed with MALDI-TOF-MS (Autoflex LRF manufactured by Bruker Co., Ltd.).

### (MALDI-TOF-MS)

Measured value: m/z=1028.66
Calculated value: C₈₀H₆₈=1028.53

### Example 3

Synthesis of exemplified compound B32: The exemplified compound B32 was synthesized by the same method as in Example 1 except that compound E13 and compound E14 below were used in place of compound E1 and compound E4, respectively, used in Example 1(1).

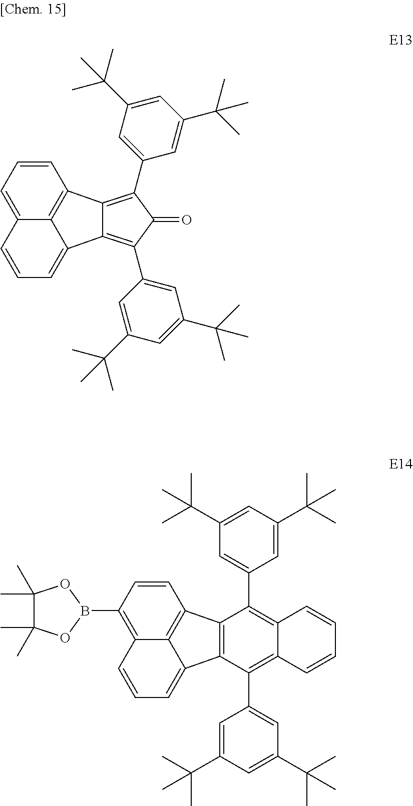

Evaluation of the purity of this compound by HPLC confirmed that the purity was 99 percent or more. As a result of measurement of an emission spectrum of a toluene solution (concentration: 1*10⁻⁵ mol/L) of exemplified compound B32 by the same method as in Example 1, a spectrum having a peak intensity at 517 nm was obtained. In addition, mass spectrometry was performed with MALDI-TOF-MS (Autoflex LRF manufactured by Bruker Co., Ltd.).

### (MALDI-TOF-MS)

Measured value: m/z=1252.12
Calculated value: C₉₆H₁₀₀=1252.78

### Example 4

Synthesis of exemplified compound B33: The exemplified compound B33 was synthesized by the same method as in Example 1 except that compound E15 and compound E16 below were used in place of compound E1 and compound E4, respectively, used in Example 1(1).

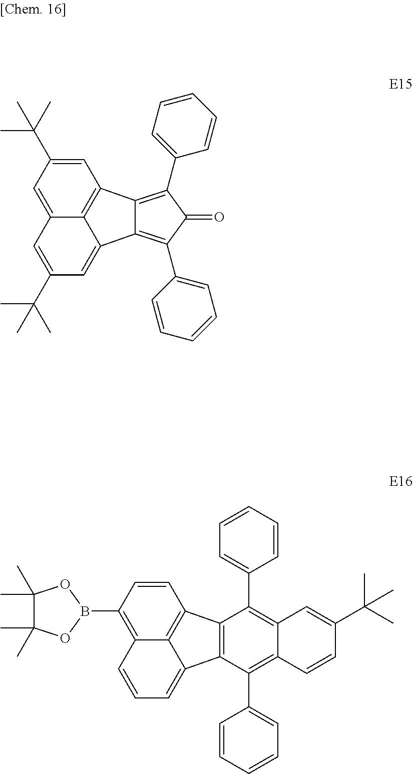 [SMILES: CC(C)(C)c1cc2c3c(cc(C(C)(C)C)cc3c1)C1=C(c3ccccc3)C(=O)C(c3ccccc3)=C12 ; CC(C)(C)c1ccc2c(-c3ccccc3)c3c(c(-c4ccccc4)c2c1)-c1ccc(B2OC(C)(C)C(C)(C)O2)c2cccc-3c12]

Evaluation of the purity of this compound by HPLC confirmed that the purity was 98 percent or more. As a result of measurement of an emission spectrum of a toluene solution (concentration: 1*10⁻⁵ mol/L) of exemplified compound B33 by the same method as in Example 1, a spectrum having a peak intensity at 516 nm was obtained. In addition, mass spectrometry was performed with MALDI-TOF-MS (Autoflex LRF manufactured by Bruker Co., Ltd.).

### (MALDI-TOF-MS)

Measured value: m/z=972.18
Calculated value: C₇₆H₆₀=972.47

### Example 5

Procedures for forming an organic EL element with a top-emission type structure shown in FIG. 1 are described below.

Ti was deposited to 40 nm on the glass substrate 1 by a sputtering method and then patterned using a known photolithographic technique to form the anode 2. In this case, an electrode area of a counter electrode (a metal electrode layer, cathode) was 3 mm².

Then, the substrate with the electrode formed thereon, which had been washed, and a material were attached to a vacuum deposition apparatus (manufactured by Ulvac, Inc.) and then washed with UV/ozone after the apparatus was evacuated to 1.33*10⁻⁴ Pa (1*10⁻⁶ Torr). Then, each of the layers of a layer configuration shown below was deposited.

TABLE 2

| | | | | Thickness |
|---|---|---|---|---|
| | | Material | | (nm) |
| Hole transport layer (HT1) | | H22 | | 25 |
| Electron blocking layer (HT2) | | H24 | | 10 |
| Second | Second host | H1 | Mass ratio | 10 |
| light-emitting layer | G dopant | B3 | H1:B3:C1 = | |
| | R dopant | C1 | 97.5:2.0:0.5 | |
| First light-emitting | First host | H1 | Mass ratio | 10 |
| layer | B dopant | A2 | H1:A2 = 99.4:0.6 | |

| | | |
|---|---|---|
| Hole blocking layer (ET1) | H4 | 10 |
| First electron transport layer (ET2) | H12 | 10 |
| Second electron transport layer | H12 + Cs (mass ratio | 30 |
| (ET3) | H12:Cs = 77.0:23.0) | |

After the second electron transport layer was formed, ITO was deposited to 500 nm by a sputtering method. Then, the substrate was moved into a glove box and sealed with a glass cap containing a drying agent in a nitrogen atmosphere to produce a white organic EL element.

On the other hand, thin films of the host and the dopant of each light-emitting layer were formed by vacuum deposition and measured with respect to HOMO energy by an atmospheric photoelectron spectrometer (apparatus name “AC-2”). In addition, a band gap and LUMO energy were calculated based on measurement of an ultraviolet-visible light absorption spectrum (apparatus name “U-3010”). The HOMO energies of H1 as the first and second hosts, B3 as the G dopant, A2 as the B dopant, and C1 as the R dopant were Hh1=Hh2=−5.8 eV, Hg2=−5.7 eV, Hg1=−5.9 eV, and −5.4 eV, respectively. Similarly, the LUMO energies of H1 as the first and second hosts, B3 as the G dopant, A2 as the B dopant, and C1 as the R dopant were Lh1=Lh2=−2.9 eV, Lg2=−3.4 eV, Lg1=−3.2 eV, and −3.5 eV, respectively. These results revealed that any one of the dopants has an electron trap deeper than a hole trap and thus has the electron trapping property.

Further, a voltage application apparatus not shown was connected to the resultant white organic EL element, and the characteristics thereof were evaluated. The current-voltage characteristics were measured using a microammeter 4140B manufactured by Hewlett-Packard Company, and chromaticity was evaluated with “SR-3” manufactured by Topcon Corporation. The luminance was measured with BM7 manufactured by Topcon Corporation. As a result, a good white organic EL element was produced, in which in a display with 1000 cd/m², the efficiency, voltage, and CIE chromaticity coordinates were 6.4 cd/A, 3.2 V, and (0.36, 0.36), respectively. In addition, a continuous driving test with an initial luminance of 4000 cd/m² showed a luminance half-time of 2700 hours and good durability characteristic.

### Examples 6 to 11

A white organic EL element of each of Examples 6 to 11 was produced by the same method as in Example 5 except that HT1, HT2, the second host, the first host, ET1, ET2, ET3, the G dopant, R dopant, and B dopant used in Example 5 were appropriately changed to compounds shown in Table 3. In addition, the concentration ratio of the second electron transport layer (ET3) was the same as in Example 5. The characteristics of the resultant white organic EL elements were measured and evaluated by the same methods as in Example 5. The results are shown in Table 3.

TABLE 3

| | | | | | | | | | | | Luminous | | |
|---|---|---|---|---|---|---|---|---|---|---|---|---|---|
| | | | Second | First | | | | B | G | R | efficiency | Chromaticity | Half-time |
| | HT1 | HT2 | host | host | ET1 | ET2 | ET3 | dopant | dopant | dopant | (cd/A) | (X, Y) | (h) |
| Example 6 | H22 | H25 | H1 | H3 | H4 | H12 | H12 + Cs | A13 | B7 | C4 | 6 | (0.36, 0.36) | 2700 |
| Example 7 | H22 | H24 | H10 | H9 | H16 | H12 | H12 + Cs | A8 | B16 | C9 | 6 | (0.35, 0.36) | 2000 |
| Example 8 | H21 | H24 | H2 | H2 | H4 | H13 | H13 + Cs | A2 | B18 | C1 | 6 | (0.35, 0.36) | 1500 |
| Example 9 | H22 | H24 | H1 | H1 | H5 | H12 | H12 + Cs | A16 | B5 | C10 | 6 | (0.36, 0.36) | 2700 |
| Example 10 | H22 | H24 | H18 | H1 | H16 | H13 | H13 + Cs | A17 | B9 | C12 | 6 | (0.36, 0.36) | 2200 |
| Example 11 | H22 | H25 | H1 | H3 | H4 | H12 | H12 + Cs | A18 | B3 | C1 | 6 | (0.36, 0.36) | 2600 |

In addition, the HOMO energy and LUMO energy of each of the materials used in the light-emitting layers are shown in Table 4

TABLE 4

| B dopant | | | G dopant | | | R dopant | | | Host | | |
|---|---|---|---|---|---|---|---|---|---|---|---|
| | HOMO | LUMO | | HOMO | LUMO | | HOMO | LUMO | | HOMO | LUMO |
| | (eV) | (eV) | | (eV) | (eV) | | (eV) | (eV) | | (eV) | (eV) |
| A2 | −5.9 | −3.2 | B3 | −5.7 | −3.4 | C1 | −5.4 | −3.5 | H1 | −5.8 | −2.9 |
| A8 | −5.9 | −3.2 | B5 | −5.8 | −3.3 | C4 | −5.4 | −3.5 | H2 | −5.7 | −2.8 |
| A13 | −5.7 | −3.1 | B7 | −5.7 | −3.4 | C9 | −5.3 | −3.4 | H3 | −5.8 | −2.8 |
| A16 | −5.9 | −3.2 | B9 | −5.7 | −3.3 | C10 | −5.3 | −3.4 | H9 | −5.9 | −2.9 |
| A17 | −5.9 | −3.2 | B16 | −5.7 | −3.2 | C12 | −5.6 | −3.6 | H10 | −5.9 | −2.9 |
| A18 | −6.0 | −3.3 | B18 | −5.2 | −2.4 | — | — | — | H18 | −5.6 | −3.0 |

### Comparative Example 1

An organic EL element of Comparative Example 1 was produced by the same method as in Example 5 except that the deposition order of the first and second light-emitting layers was reversed. As a result of evaluation, the chromaticity coordinates were (0.48, 0.46), and good white could not be realized.

### Example 12

In this example, an organic EL element with a bottom-emission type structure was formed, in which an anode, a hole transport layer, a second light-emitting layer, a first light-emitting layer, a hole blocking layer, an electron transport layer, and a cathode were sequentially formed on a substrate.

First, ITO was deposited on a glass substrate and an ITO electrode (anode) was formed by desired patterning. In this case, the thickness of the ITO electrode was 100 nm. The substrate having the ITO electrode formed thereon was used as an ITO substrate in subsequent steps. Next, organic EL layers shown in Table 5 and an electrode layer were continuously deposited on the ITO substrate by resistance-heating vacuum deposition in a vacuum chamber of 1.33*10⁻⁴ Pa. In this case, the electrode area of a counter electrode (metal electrode layer, cathode) was 3 mm².

TABLE 5

| | | | | Thickness |
|---|---|---|---|---|
| | | Material | | (nm) |
| Hole transport layer (HT1) | | H22 | | 30 |
| Electron blocking layer (HT2) | | H29 | | 10 |
| Second | Second host | H1 | Mass ratio | 20 |
| light-emitting layer | G dopant | B32 | H1:B32:C1 = | |
| | R dopant | C1 | 95.0:4.5:0.5 | |
| First light-emitting | First host | H39 | Mass ratio | 20 |
| layer | B dopant | A2 | H39:A2 = | |
| | | | 96.0:4.0 | |

| | | |
|---|---|---|
| Hole blocking layer (ET1) | H31 | 10 |
| First electron transport layer (ET2) | H12 | 30 |

After the first electron transport layer was formed, LiF was deposited to 1 nm by a vapor deposition method, and Al was deposited to 100 nm by a sputtering method. Then, the substrate was moved into a glove box and sealed with a glass cap containing a drying agent in a nitrogen atmosphere to produce a white organic EL element.

The characteristics of the resultant organic EL element were measured and evaluated. Specifically, the current-voltage characteristics were measured using a microammeter 4140B manufactured by Hewlett-Packard Company, and chromaticity was evaluated with “SR-3” manufactured by Topcon Corporation. The luminance was measured with BM7 manufactured by Topcon Corporation. In addition, a continuous driving test with an initial luminance of 4000 cd/m² was conducted. The results of measurement are shown in Table 6. In addition, both the B dopant and the G dopant had the electron trapping property.

### Examples 13 to 15

White organic EL elements were produced by the same method as in Example 12 except that the first host, the second host, and the G dopant used in Example 12 were appropriately changed to compounds shown in Table 6. The characteristics of the resultant organic EL elements were measured and evaluated by the same methods as in Example 12. The results of measurement are shown in Table 6. In addition, both the B dopant and the G dopant had the electron trapping property.

TABLE 6

| | | | | Luminous | | Half- |
|---|---|---|---|---|---|---|
| | First | Second | G | efficiency | Chromaticity | time |
| | host | host | dopant | (cd/A) | (X, Y) | (h) |
| Example 12 | H39 | H1 | B32 | 14 | (0.33, 0.36) | 2000 |
| Example 13 | H1 | H1 | B30 | 15 | (0.34, 0.36) | 1800 |
| Example 14 | H30 | H11 | B33 | 13 | (0.34, 0.36) | 2000 |
| Example 15 | H37 | H27 | B36 | 13 | (0.34, 0.36) | 2100 |

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefits of Japanese Patent Application No. 2011-207325, filed Sep. 22, 2011, and Japanese Patent Application No. 2012-160120, filed Jul. 19, 2012, which are hereby incorporated by reference herein in its entirety.

1. A white organic EL element comprising:
an anode;
a cathode; and
a plurality of laminated light-emitting layers arranged between the anode and cathode,
wherein the plurality of light-emitting layers contain respective dopants having different emission colors;
among the plurality of light-emitting layers, the light-emitting layer closest to the cathode side contains a first host and a blue light-emitting dopant, and the other light-emitting layers contain a green light-emitting dopant and a red light-emitting dopant; and
Lh1−Lg1>Hg1−Hh1 is satisfied, wherein Lh1 is the lowest unoccupied molecular orbital energy of the first host, Hh1 is the highest occupied molecular orbital energy of the first host, Lg1 is the lowest unoccupied molecular orbital energy of the blue light-emitting dopant, and Hg1 is the highest occupied molecular orbital energy of the blue light-emitting dopant.

2. The white organic EL element according to claim 1, wherein the plurality of light-emitting layers include two light-emitting layers; the other light-emitting layer contains a second host, a green light-emitting dopant, and a red light-emitting dopant; and
Lh2−Lg2>Hg2−Hh2 is satisfied, wherein Lh2 is the lowest unoccupied molecular orbital energy of the second host, Hh2 is the highest occupied molecular orbital energy of the second host, Lg2 is the lowest unoccupied molecular orbital energy of the green light-emitting dopant, and Hg2 is the highest occupied molecular orbital energy of the green light-emitting dopant.

3. The white organic EL element according to claim 2, wherein the first host and the second host are composed of the same material.

4. The white organic EL element according to claim 1, wherein the plurality of light-emitting layers include three light-emitting layers; among the other light-emitting layers, the light-emitting layer on the anode side contains a third host and a red light-emitting dopant, and the light-emitting layer on the cathode side contains a second host and a green light-emitting dopant; and
Lh2−Lg2>Hh2−Hg2 is satisfied, wherein Lh2 is the lowest unoccupied molecular orbital energy of the second host, Hh2 is the highest occupied molecular orbital energy of the second host, Lg2 is the lowest unoccupied molecular orbital energy of the green light-emitting dopant, and Hg2 is the highest occupied molecular orbital energy of the green light-emitting dopant.

5. An illuminating apparatus comprising:
the organic EL element according to claim 1; and a converter circuit connected to the white organic EL element.

6. A display apparatus comprising:
the organic EL element according to claim 1; and a switching element connected to the white organic EL element.

7. An electrophotographic image forming apparatus comprising an exposure light source,
wherein the exposure light source comprising the white organic EL element according to claim 1.

8. An exposure light source of an electrophotographic image forming apparatus comprising the white organic EL element according to claim 1.
